(19) United States
(12) Patent Application Publication
(10) Pub. No.: US 2025/0374777 A1
(43) Pub. Date: Dec. 4, 2025

(54) DISPLAY APPARATUS

(71) Applicant: Samsung Display Co., Ltd., Yongin-Si (KR)

(72) Inventors: Junghyun Kwon, Yongin-si (KR); Moonjung Baek, Yongin-si (KR); Soonkyeong Kwon, Yongin-si (KR); Youngmin Kim, Yongin-si (KR); Hyunwoo Noh, Yongin-si (KR); Daeho Lee, Yongin-si (KR); Kyungjin Jeon, Yongin-si (KR); Suji Han, Yongin-si (KR)

(21) Appl. No.: 19/023,318

(22) Filed: Jan. 16, 2025

(30) Foreign Application Priority Data
May 31, 2024 (KR) 10-2024-0071811

(51) Int. Cl. H10K 59/131; H10H 29/37; H10H 29/49; H10H 29/854; H10H 29/855; H10K 59/122; H10K 59/80

(52) U.S. Cl. CPC H10K 59/131; H10H 29/37; H10H 29/49; H10H 29/854; H10H 29/8552; H10K 59/122; H10K 59/8731; H10K 59/8792

(57) ABSTRACT

A display apparatus includes a substrate, a pixel circuit layer disposed on the substrate and including a pixel circuit, a metal layer disposed on the pixel circuit layer, a pixel electrode disposed on the metal layer, a first bank layer disposed on the pixel electrode to cover the metal layer and including a first opening extending to at least a portion of the pixel electrode, an intermediate layer disposed on the pixel electrode and the first bank layer, an opposite electrode disposed on the intermediate layer, a first connection electrode disposed on the opposite electrode, and a second bank layer disposed on the first bank layer to cover at least a portion of the first connection electrode and including a second opening overlapping the first opening.

### CROSS-REFERENCE TO RELATED APPLICATION

This application is based on and claims priority under 35 U.S.C. § 119 to Korean Patent Application No. 10-2024-0071811, filed on May 31, 2024, in the Korean Intellectual Property Office, the disclosure of which is incorporated by reference herein in its entirety.

### BACKGROUND

### 1. Field

One or more embodiments relate to an apparatus, and more specifically, to a display apparatus.

### 2. Description of the Related Art

Electronic devices based on mobility are widely used. In addition to small electronic devices such as mobile phones, tablet personal computers (PCs) have recently been widely used as mobile electronic devices.

Such mobile electronic devices include display apparatuses to support various functions and provide visual information such as images or videos to users. Recently, as other components for driving display apparatuses have become smaller, the proportion of display apparatuses in electronic devices is gradually increasing, and structures that may be bent to have a certain angle from a flat state are also being developed.

### SUMMARY

One or more embodiments include a display apparatus that has reduced quality degradation caused by external light reflection and has improved light efficiency. However, such a feature is exemplary, and the features of the disclosure to solve is not limited thereby.

Additional aspects will be set forth in part in the description which follows and, in part, will be apparent from the description, or may be learned by practice of the presented embodiments of the disclosure.

According to one or more embodiments, a display apparatus includes a substrate, a pixel circuit layer disposed on the substrate and including a pixel circuit, a metal layer disposed on the pixel circuit layer, a pixel electrode disposed on the metal layer, a first bank layer disposed on the pixel electrode to cover the metal layer and including a first opening extending to at least a portion of the pixel electrode, an intermediate layer disposed on the pixel electrode and the first bank layer, an opposite electrode disposed on the intermediate layer, a first connection electrode disposed on the opposite electrode, and a second bank layer disposed on the first bank layer to cover at least a portion of the first connection electrode and including a second opening overlapping the first opening. The metal layer includes a first metal layer electrically connected to the pixel circuit, a second metal layer disposed on the first metal layer and having a width smaller than a width of the first metal layer, and a third metal layer disposed on the second metal layer and having a width larger than the width of the second metal layer.

In the present embodiment, the second bank layer may include a black organic material.

In the present embodiment, the first bank layer may be in contact with a side surface of the second metal layer.

In the present embodiment, the pixel electrode has a width smaller than the width of the third metal layer.

In the present embodiment, the opposite electrode and the first connection electrode may be in a form of an isolated island.

In the present embodiment, the first metal layer and the third metal layer may include a same material, and the second metal layer may include a material different from the material of the first metal layer and the third metal layer.

In the present embodiment, each of the first metal layer and the third metal layer may include titanium (Ti), and the second metal layer may include aluminum (Al).

In the present embodiment, the display apparatus may further include a second connection electrode covering the first connection electrode and the second bank layer.

In the present embodiment, the display apparatus may further include an encapsulation layer including an organic encapsulation layer disposed on the second connection electrode to be in contact with the second connection electrode, and a first inorganic encapsulation layer disposed on the organic encapsulation layer.

In the present embodiment, the display apparatus may further include an encapsulation layer including a second inorganic encapsulation layer disposed on the second connection electrode to be in contact with the second connection electrode, an organic encapsulation layer disposed on the second inorganic encapsulation layer, and a first inorganic encapsulation layer disposed on the organic encapsulation layer.

According to one or more embodiments, a display apparatus includes a substrate, a pixel circuit layer disposed on the substrate and including a pixel circuit, a metal layer disposed on the pixel circuit layer, a pixel electrode disposed on the metal layer, a first bank layer disposed on the pixel electrode to cover the metal layer and including a first opening extending to at least a portion of the pixel electrode, an intermediate layer disposed on the pixel electrode and the first bank layer, a reflective layer disposed on the intermediate layer, a second bank layer disposed on the first bank layer to cover at least a portion of the reflective layer and including a second opening overlapping the first opening, and an opposite electrode covering the second bank layer. The reflective layer includes a third opening overlapping the first opening, and the opposite electrode is in contact with the intermediate layer via the third opening.

In the present embodiment, the second bank layer may include a black organic material.

In the present embodiment, the metal layer may include a first metal layer electrically connected to the pixel circuit, a second metal layer disposed on the first metal layer and having a width smaller than a width of the first metal layer, and a third metal layer disposed on the second metal layer and having a width larger than the width of the second metal layer.

In the present embodiment, the first bank layer may be in contact with a side surface of the second metal layer.

In the present embodiment, the pixel electrode has a width the same as the width of the third metal layer.

In the present embodiment, the first metal layer and the third metal layer may include a same material, and the second metal layer may include a material different from the material of the first metal layer and the third metal layer.

In the present embodiment, each of the first metal layer and the third metal layer may include titanium (Ti), and the second metal layer may include aluminum (Al).

In the present embodiment, the reflective layer may be in a form of an isolated island.

In the present embodiment, the display apparatus may further include a third connection electrode disposed on the opposite electrode to be in contact with the opposite electrode, and an encapsulation layer including an organic encapsulation layer disposed on the third connection electrode and a first inorganic encapsulation layer disposed on the organic encapsulation layer.

In the present embodiment, the display apparatus may further include an encapsulation layer including a third inorganic encapsulation layer disposed on the opposite electrode to be in contact with the opposite electrode, an organic encapsulation layer disposed on the third inorganic encapsulation layer, and a first inorganic encapsulation layer disposed on the organic encapsulation layer.

Other aspects, features, and advantages other than those described above will become apparent from the following drawings, claims, and detailed description of the disclosure.

### BRIEF DESCRIPTION OF THE DRAWINGS

The above and other aspects, features, and advantages of certain embodiments of the disclosure will be more apparent from the following description taken in conjunction with the accompanying drawings.

FIG. 1 is a schematic perspective view of a display apparatus according to an embodiment.

FIG. 2 is a schematic equivalent circuit diagram of a light-emitting element corresponding to any one pixel of a display apparatus according to an embodiment, and a pixel circuit electrically connected to the light-emitting element.

FIGS. 3A and 3B are schematic cross-sectional views of a display apparatus according to an embodiment.

FIGS. 4A, 4B, 4C, 4D, 4E, 4F, 4G, 4H, 4I, 4J, and 4K are schematic cross-sectional views of a display apparatus according to an embodiment.

FIG. 5 is a schematic cross-sectional view of a display apparatus according to an embodiment.

FIGS. 6A and 6B are schematic cross-sectional views of a display apparatus according to another embodiment.

FIGS. 7A, 7B, 7C, 7D, 7E, 7F, 7G, 7H, 7I, 7J, 7K, and 7L are schematic cross-sectional views of a display apparatus according to an embodiment.

FIG. 8 is a schematic cross-sectional view of a display apparatus according to an embodiment.

### DETAILED DESCRIPTION

Reference will now be made in detail to embodiments, examples of which are illustrated in the accompanying drawings, wherein like reference numerals refer to like elements throughout the present specification. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof. Various modifications may be applied to the present embodiments, and particular embodiments will be illustrated in the drawings and described in the detailed description section. The effect and features of the disclosure, and a method to achieve the same, will be clearer referring to the detailed descriptions below with the drawings. However, the present embodiments may be implemented in various forms, not by being limited to the embodiments presented below.

Hereinafter, embodiments of the present disclosure will be described in detail with reference to the accompanying drawings, and in the description with reference to the drawings, the same or corresponding components are indicated by the same reference numerals and redundant descriptions thereof are omitted.

In the following embodiment, it will be understood that although the terms “first,” “second,” etc. may be used herein to describe various components, these components should not be limited by these terms. These terms are only used to distinguish one component from another.

In the following embodiment, the expression of singularity in the present specification includes the expression of plurality unless clearly specified otherwise in context.

In the following embodiment, it will be further understood that the terms “comprises” and/or “comprising” used herein specify the presence of stated features or components, but do not preclude the presence or addition of one or more other features or components.

In the following embodiment, it will be understood that when a layer, region, or component is referred to as being “formed on” another layer, region, or component, it can be directly or indirectly formed on the other layer, region, or component. That is, for example, intervening layers, regions, or components may be present.

Sizes of components in the drawings may be exaggerated for convenience of explanation. In other words, since sizes and thicknesses of components in the drawings are arbitrarily illustrated for convenience of explanation, the following embodiments are not limited thereto.

In the following embodiment, the x-axis, the y-axis, and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

When a certain embodiment may be implemented differently, a specific process order may be performed differently from the described order. For example, two consecutively described processes may be performed substantially at the same time or performed in an order opposite to the described order.

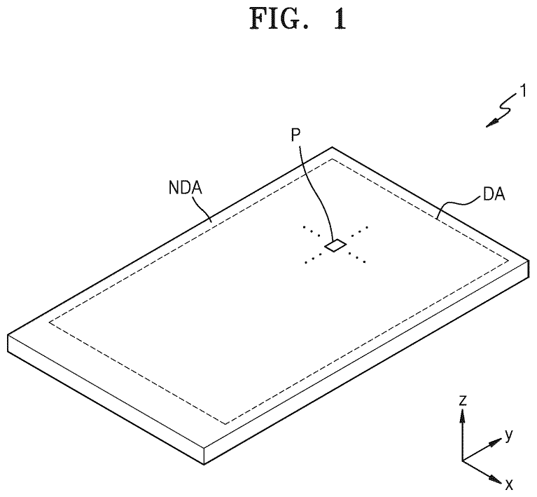

FIG. 1 is a schematic perspective view of a display apparatus 1 according to an embodiment.

Referring to FIG. 1, the display apparatus 1 may include a display region DA and a non-display region NDA located outside the display region DA. The display region DA may display an image via pixels P arranged in the display region DA. The non-display region NDA is arranged outside the display region DA and does not display an image, and may entirely surround the display region DA. In the non-display region NDA, a driver may be arranged to provide an electrical signal or power to the display region DA. In the non-display region NDA, a pad that is a region to which an electronic device or a printed circuit board may be electrically connected may be arranged.

In an embodiment, FIG. 1 shows that the display region DA is a polygon (for example, a quadrangle) of which the length in an x direction is smaller than the length in a y direction, but in an embodiment, the display region DA may be a polygon (for example, a quadrangle) of which the length in the y direction is smaller than the length in the x direction. FIG. 1 shows that the display region DA is a quadrangle, but the disclosure is not limited thereto. In an embodiment, the display region DA may have various shapes such as an N-gon shape (N is a natural number of 3 or more), a circular shape, or an elliptical shape. FIG. 1 shows that corner portions of the display region DA have a shape that includes a vertex where two straight lines meet, but in an embodiment, the display region DA may be a polygon having rounded corner portions.

Hereinafter, for convenience of explanation, a case where the display apparatus 1 is an electronic device such as a smartphone is described, but the display apparatus 1 of the disclosure is not limited thereto. The display apparatus 1 may be applied not only to portable electronic devices such as mobile phones, smartphones, tablet personal computers (PCs) mobile communication terminals, electronic organizers, electronic books, portable multimedia players (PMPs), navigation devices, and ultra-mobile PCs (UMPCs), but also to various other products such as televisions, laptops, monitors, billboards, and Internet of things (IoT) devices. In addition, the display apparatus 1 according to an embodiment may be applied to wearable devices such as smart watches, watch phones, glasses-type displays, and head-mounted displays (HMDs). In addition, the display apparatus 1 according to an embodiment may be applied to an instrument panel of vehicles, a center information display (CID) arranged on the center fascia or dashboard of vehicles, a room mirror display in place of side-view mirrors of vehicles, or a display screen arranged at the rear side of a front seat as an entertainment for a rear set of vehicles.

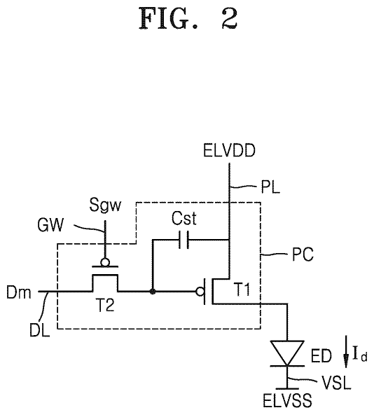

FIG. 2 is a schematic equivalent circuit diagram of a light-emitting element ED corresponding to any one pixel P (see FIG. 1) of the display apparatus 1 (see FIG. 1) according to an embodiment, and a pixel circuit PC electrically connected to the light-emitting element ED.

Referring to FIG. 2, the light-emitting element ED is electrically connected to the pixel circuit PC, and the pixel circuit PC may include a first transistor T1, a second transistor T2, and a storage capacitor Cst. A pixel electrode (for example, an anode) of the light-emitting element ED may be electrically connected to the first transistor T1, and an opposite electrode (for example, a cathode) may be electrically connected to an auxiliary wire VSL and may receive a voltage corresponding to a common voltage ELVSS via the auxiliary wire VSL.

The second transistor T2 may be configured to transfer, to the first transistor T1, a data signal Dm which is input via a data line DL according to a scan signal Sgw which is input via a scan line GW.

The storage capacitor Cst is connected to the second transistor T2 and a driving voltage line PL and is configured to store a voltage corresponding to a difference between a voltage received from the second transistor T2 and a driving voltage ELVDD supplied to the driving voltage line PL.

The first transistor T1 is connected to the driving voltage line PL and the storage capacitor Cst, and may be configured to control a driving current Id flowing from the driving voltage line PL to the light-emitting element ED according to a voltage value stored in the storage capacitor Cst. The light-emitting element ED may emit light having a certain luminance according to the driving current Id.

A case where the pixel circuit PC includes two transistors T1, T2 and one storage capacitor Cst is described with reference to FIG. 2, but the disclosure is not limited thereto.

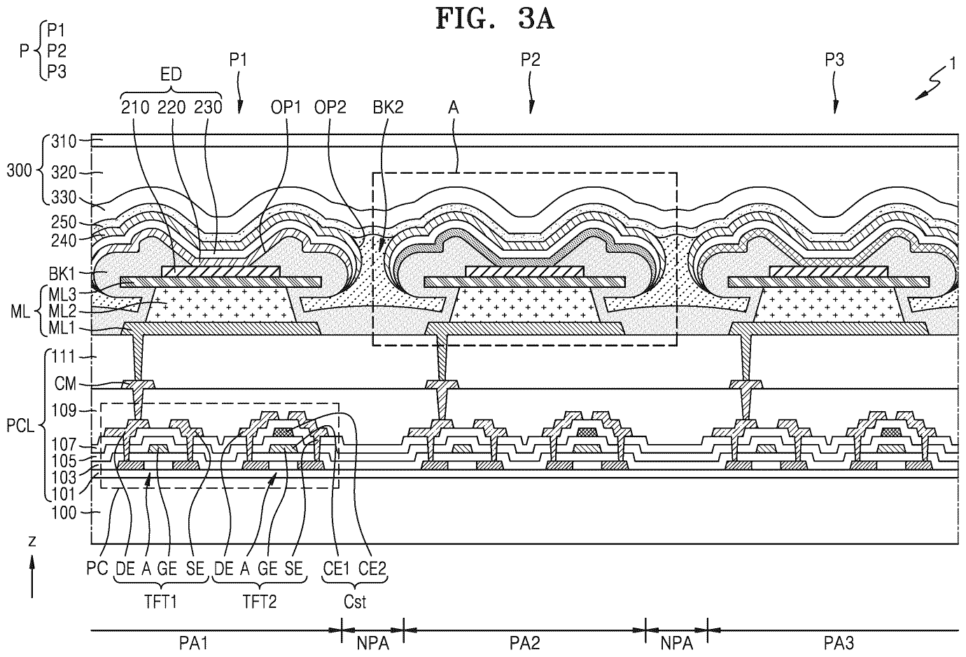

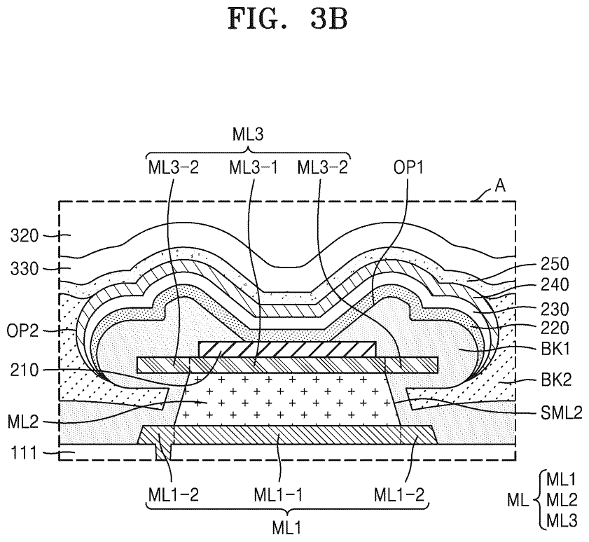

FIGS. 3A and 3B are schematic cross-sectional views of the display apparatus 1 according to an embodiment.

In detail, FIG. 3B is an enlarged view of a region A of FIG. 3A.

Referring to FIGS. 3A and 3B, the display apparatus 1 may include a substrate 100, a pixel circuit layer PCL, a metal layer ML, a light-emitting element ED, a first bank layer BK1, a second bank layer BK2, a first connection electrode 240, a second connection electrode 250, and an encapsulation layer 300.

A pixel P shown in FIG. 1 may include a first pixel P1, a second pixel P2, and a third pixel P3. At this time, in the display apparatus 1, a region in which the first pixel P1 is arranged is referred to as a first pixel region PA1, a region in which the second pixel P2 is arranged is referred to as a second pixel region PA2, and a region in which the third pixel P3 is arranged is referred to as a third pixel region PA3.

The display apparatus 1 may include the first to third pixel regions PA1, PA2, and PA3 and a non-pixel region NPA between neighboring pixel regions. The planar shape of the display apparatus 1 may be substantially the same as the planar shape of the substrate 100. Accordingly, describing that the display apparatus 1 includes the first to third pixel regions PA1, PA2, and PA3 and the non-pixel region NPA may indicate that the substrate 100 includes the first to third pixel regions PA1, PA2, and PA3 and the non-pixel region NPA.

At this time, the light-emitting element ED may be provided as a plurality of light-emitting elements ED to correspond to a plurality of pixel regions. For example, as shown in FIG. 3A, three light-emitting elements ED may be provided to correspond to the first to third pixel regions PA1, PA2, and PA3.

The substrate 100 may include glass material or polymer resin. The substrate 100 may include a structure in which a base layer including polymer resin and an inorganic barrier layer are stacked. Polymer resin may be polyethersulfone (PES), polyacrylate (PAR), polyetherimide (PEI), polyethylene naphthalate (PEN), polyethylene terephthalate (PET), polyphenylene sulfide (PPS), polyarylate, polyimide (PI), polycarbonate, cellulose triacetate (TAC), or cellulose acetate propionate (CAP).

The pixel circuit layer PCL may be disposed on the substrate 100. The pixel circuit layer PCL may include a buffer layer 101, a first gate insulating layer 103, a first interlayer insulating layer 105, a second interlayer insulating layer 107, a first organic insulating layer 109, a second organic insulating layer 111, and a pixel circuit PC.

The buffer layer 101 may be disposed on an upper surface of the substrate 100. The buffer layer 101 may prevent penetration of impurities into a semiconductor layer of a transistor. The buffer layer 101 may include an inorganic insulating material such as silicon nitride, silicon oxynitride, and silicon oxide, and may be a single layer or a multilayer, including the above-described inorganic insulating material.

The pixel circuit PC may be disposed on the buffer layer 101. The pixel circuit PC may be arranged between the substrate 100 and the light-emitting element ED. The pixel circuit PC may include a transistor and a storage capacitor, as described with reference to FIG. 2. In an embodiment, FIG. 3A shows a first thin-film transistor TFT1, a second thin-film transistor TFT2, and a storage capacitor Cst.

Each of the first thin-film transistor TFT1 and the second thin-film transistor TFT2 may include a semiconductor layer A on the buffer layer 101, and a gate electrode GE overlapping a channel region of the semiconductor layer A. Each of the first thin-film transistor TFT1 and the second thin-film transistor TFT2 may further include a source electrode SE and/or a drain electrode DE, which is electrically connected to the semiconductor layer A.

The semiconductor layer A may be disposed on the buffer layer 101. The semiconductor layer A may include a silicon-based semiconductor material, for example, polysilicon. The semiconductor layer A may include a channel region and a first region and a second region, which are respectively arranged at both sides of the channel region. The first region and the second region include higher concentrations of impurities than the channel region, and any one of the first region and the second region may be a source region and the other may correspond to a drain region.

The gate electrode GE may be arranged over the semiconductor layer A with the first gate insulating layer 103 therebetween. The gate electrode GE may overlap the channel region of the semiconductor layer A. The gate electrode GE may include a low-resistance metal material. The gate electrode GE may include a conductive material including molybdenum (Mo), aluminum (Al), copper (Cu), or titanium (Ti), and may include a single-layer or multilayer structure including the above-described material.

The first gate insulating layer 103 may be disposed on the buffer layer 101. The first gate insulating layer 103 may be arranged between the semiconductor layer A and the gate electrode GE. The first gate insulating layer 103 may include an inorganic insulating material such as silicon nitride, silicon oxynitride, and silicon oxide, and may be a single layer or a multilayer, including the above-described inorganic insulating material.

The first interlayer insulating layer 105 may be disposed on the first gate insulating layer 103. The first interlayer insulating layer 105 may cover the gate electrode GE. The first interlayer insulating layer 105 may include an inorganic insulating material such as silicon nitride, silicon oxynitride, and silicon oxide, and may be a single layer or a multilayer, including the above-described inorganic insulating material.

The storage capacitor Cst may include a lower electrode CE1 and an upper electrode CE2, which overlap each other. The upper electrode CE2 of the storage capacitor Cst may be disposed on the first interlayer insulating layer 105. In an embodiment, the upper electrode CE2 may overlap the gate electrode GE of the second thin-film transistor TFT2. At this time, the gate electrode GE of the second thin-film transistor TFT2 and the upper electrode CE2, which overlap each other with the first interlayer insulating layer 105 therebetween, may form the storage capacitor Cst. In other words, the gate electrode GE of the second thin-film transistor TFT2 may function as the lower electrode CE1 of the storage capacitor Cst. As such, the storage capacitor Cst and the second thin-film transistor TFT2 may overlap each other.

The upper electrode CE2 of the storage capacitor Cst may include a low-resistance conductive material such as molybdenum (Mo), aluminum (Al), copper (Cu), and/or titanium (Ti), and may include a single-layer or multilayer structure including the above-described material.

The second interlayer insulating layer 107 may be disposed on the storage capacitor Cst. The second interlayer insulating layer 107 may include an inorganic insulating material such as silicon oxide, silicon nitride, and silicon oxynitride, and may include a single-layer or multilayer structure including the above-described inorganic insulating material.

The source electrode SE and/or the drain electrode DE, which is electrically connected to the semiconductor layer A, may be disposed on the second interlayer insulating layer 107. The source electrode SE and/or the drain electrode DE may include aluminum (Al), copper (Cu), and/or titanium (Ti), and may be formed as a single layer or a multilayer, including the above-described material.

The first organic insulating layer 109 may be disposed on the pixel circuit PC. The first organic insulating layer 109 may include an organic insulating material such as acryl, benzocyclobutene (BCB), PI, or hexamethyldisiloxane (HMDSO).

A connection metal CM may be disposed on the first organic insulating layer 109. The connection metal CM may include aluminum (Al), copper (Cu), and/or titanium (Ti), and may be formed as a single layer or a multilayer, including the above-described material.

The second organic insulating layer 111 may be arranged between the connection metal CM and the metal layer ML. The second organic insulating layer 111 may include an organic insulating material such as acryl, BCB, PI, or HMDSO.

According to the embodiment described with reference to FIG. 3A, it is shown that the pixel circuit PC and the metal layer ML are electrically connected to each other via the connection metal CM, but according to an embodiment, the connection metal CM may be omitted, and one organic insulating layer may be located between the pixel circuit PC and the metal layer ML. In an embodiment, at least three organic insulating layers may be located between the pixel circuit PC and the metal layer ML, and the pixel circuit PC and the metal layer ML may be electrically connected to each other via a plurality of connection metals.

The metal layer ML may be disposed on the pixel circuit layer PCL. The metal layer ML may include a first metal layer ML1, a second metal layer ML2, and a third metal layer ML3.

The first metal layer ML1 may be disposed on the pixel circuit layer PCL and electrically connected to the pixel circuit PC. For example, the first metal layer ML1 may contact the connection metal CM through the second organic insulating layer 111. The second metal layer ML2 may be disposed on the first metal layer ML1, and the third metal layer ML3 may be disposed on the second metal layer ML2.

The first metal layer ML1 and the third metal layer ML3 may include a same material. For example, the first metal layer ML1 and the third metal layer ML3 may each include Ti. The second metal layer ML2 may include a different material from each of the first metal layer ML1 and the third metal layer ML3. For example, the second metal layer ML2 may include Al, Ag, Mg, Pt, Pd, Au, Ni, Nd, Ir, or Cr, or a compound thereof. However, the materials constituting the first metal layer ML1, the second metal layer ML2, and the third metal layer ML3 are only examples and are not limited to the above-described examples.

The second metal layer ML2 may have a smaller width than the first metal layer ML1. The third metal layer ML3 may have a larger width than the second metal layer ML2. The first metal layer ML1 and the third metal layer ML3 may have a same width.

The first metal layer ML1 may include a first-1 metal layer portion ML1-1 overlapping the second metal layer ML2, and a first-2 metal layer portion ML1-2 extending from the first-1 metal layer portion ML1-1. The first-2 metal layer portion ML1-2 may be arranged outside the first-1 metal layer portion ML1-1.

In addition, the third metal layer ML3 may include a third-1 metal layer portion ML3-1 overlapping the second metal layer ML2, and a third-2 metal layer portion ML3-2 extending from the third-1 metal layer portion ML3-1. The third-2 metal layer portion ML3-2 may be arranged outside the third-1 metal layer portion ML3-1.

The first-1 metal layer portion ML1-1 and the third-1 metal layer portion ML3-1 may overlap each other. In addition, the first-2 metal layer portion ML1-2 and the third-2 metal layer portion ML3-2 may overlap each other.

In this structure, the first metal layer ML1 and the third metal layer ML3 may include a tip structure protruding from the second metal layer ML2 in one direction. For example, the first-2 metal layer portion ML1-2 and the third-2 metal layer portion ML3-2 may have a tip structure protruding from the second metal layer ML2 in one direction.

The light-emitting element ED may be disposed on the third metal layer ML3 of the metal layer ML. The light-emitting element ED may include a pixel electrode 210, an intermediate layer 220, and an opposite electrode 230. The pixel electrode 210, the intermediate layer 220, and the opposite electrode 230 may be sequentially arranged in a stacked structure.

The pixel electrode 210 may be disposed on the third metal layer ML3 of the metal layer ML. The pixel electrode 210 may be electrically connected to the pixel circuit PC via the metal layer ML. The width of the pixel electrode 210 may be smaller than the width of the third metal layer ML3. The pixel electrode 210 may include metal and/or conductive oxide. The pixel electrode 210 may include indium tin oxide (ITO), indium zinc oxide (IZO), ZnO, or In₂O₃, or a compound thereof.

The first bank layer BK1 may be disposed on the pixel electrode 210 to cover the pixel circuit layer PCL and the metal layer ML. The first bank layer BK1 may be in contact with a side surface SML2 of the second metal layer ML2. The first bank layer BK1 may include a shape that is convex along the third-2 metal layer portion ML3-2. The first bank layer BK1 may include a first opening OP1 extending to and exposing at least a portion of the pixel electrode 210. The first bank layer BK1 may include an organic insulating material and/or an inorganic insulating material. The first opening OP1 may define an emission region of light emitted from the light-emitting element ED. For example, the size/width of the first opening OP1 may correspond to the size/width of the emission region. Accordingly, the size and/or width of the pixel P may depend on the size and/or width of the first opening OP1 in the first bank layer BK1.

The intermediate layer 220 may be disposed on the pixel electrode 210 and the first bank layer BK1. The intermediate layer 220 may include a polymer or low-molecular weight organic material that emits light of a certain color. In an embodiment, the intermediate layer 220 may include an inorganic light-emitting material or a quantum dot.

At least a portion of the intermediate layer 220 may be accommodated in the first opening OP1 and be in contact with the pixel electrode 210. The inner portion of the intermediate layer 220 may overlap and be in contact with the pixel electrode 210, and the outer portion may extend onto the first bank layer BK1 and overlap and be in contact with the first bank layer BK1. In this regard, the expression “the other portion of A” indicates “a portion of A including the edge of A,” and the expression “the inner portion of A” indicates another portion of A surrounded by the outer portion.

The opposite electrode 230 may be disposed on the intermediate layer 220. The opposite electrode 230 may be in contact with the intermediate layer 220. At least a portion of the opposite electrode 230 may be accommodated in the first opening OP1. The opposite electrode 230 may overlap the pixel electrode 210. The opposite electrode 230 may cover the intermediate layer 220. The opposite electrode 230 may include a conductive material having a low work function. For example, the opposite electrode 230 may include a (semi) transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof. In an embodiment, the opposite electrode 230 may further include a layer including ITO, IZO, ZnO, or In₂O₃ on the (semi) transparent layer including the above-described material.

The first connection electrode 240 may be disposed on the opposite electrode 230. At least a portion of the first connection electrode 240 may be accommodated in the first opening OP1. The first connection electrode 240 may overlap the pixel electrode 210. The first connection electrode 240 may cover the intermediate layer 220. The first connection electrode 240 may include a transparent conductive oxide (TCO).

The intermediate layer 220, the opposite electrode 230, and the first connection electrode 240 may be provided in the form of an isolated island. The intermediate layer 220 arranged in the first pixel region PA1, the intermediate layer 220 arranged in the second pixel region PA2, and the intermediate layer 220 arranged in the third pixel region PA3 may not be in contact with each other. The opposite electrode 230 arranged in the first pixel region PA1, the opposite electrode 230 arranged in the second pixel region PA2, and the opposite electrode 230 arranged in the third pixel region PA3 may not be in contact with each other. The first connection electrode 240 arranged in the first pixel region PA1, the first connection electrode 240 arranged in the second pixel region PA2, and the first connection electrode 240 arranged in the third pixel region PA3 may not be in contact with each other.

The second bank layer BK2 may be disposed on the first bank layer BK1 to cover at least a portion of the first bank layer BK1. The second bank layer BK2 may be arranged in the non-pixel region NPA. For example, the second bank layer BK2 is arranged between the first bank layer BK1 arranged in the first pixel region PA1, the first bank layer BK1 arranged in the second pixel region PA2, and the first bank layer BK1 arranged in the third pixel region PA3, and thus may serve as a planarization layer.

The second bank layer BK2 may include a second opening OP2 above and overlapping the first opening OP1. The intermediate layer 220, the opposite electrode 230, and the first connection electrode 240 may be accommodated in the second opening OP2. The second bank layer BK2 may include an organic insulating material and/or an inorganic insulating material. The second bank layer BK2 may include a black organic material and/or a black inorganic material.

The second connection electrode 250 may cover the first connection electrode 240 and the second bank layer BK2. The second connection electrode 250 may be in contact with the first connection electrode 240. In this structure, the second connection electrode 250, the first connection electrode 240, and the opposite electrode 230 may be electrically connected to each other. The second connection electrode 250 may be a common layer that is arranged throughout the first pixel region PA1, the second pixel region PA2, the third pixel region PA3, and the non-pixel region NPA. The second connection electrode 250 may include a transparent conductive oxide (TCO).

The encapsulation layer 300 may be disposed on the second connection electrode 250. The encapsulation layer 300 includes at least one inorganic encapsulation layer and at least one organic encapsulation layer 320, and in an embodiment, FIG. 3A shows that the encapsulation layer 300 includes a second inorganic encapsulation layer 330, an organic encapsulation layer 320, and a first inorganic encapsulation layer 310, which are sequentially stacked. The second inorganic encapsulation layer 330 may be disposed on the second connection electrode 250 to be in contact with the second connection electrode 250, the organic encapsulation layer 320 may be disposed on the second inorganic encapsulation layer 330, and the first inorganic encapsulation layer 310 may be disposed on the organic encapsulation layer 320.

The first inorganic encapsulation layer 310 and the second inorganic encapsulation layer 330 may include at least one inorganic material among aluminum oxide, titanium oxide, tantalum oxide, hafnium oxide, zinc oxide, silicon oxide, silicon nitride, and silicon oxynitride. The organic encapsulation layer 320 may include a polymer-based material. The polymer-based material may include acrylic resin, epoxy-based resin, PI, and polyethylene. In an embodiment, the organic encapsulation layer 320 may include acrylate. The organic encapsulation layer 320 may be formed by curing a monomer or applying a polymer. The organic encapsulation layer 320 may have transparency.

Although not shown, a touch sensor layer may be disposed on the encapsulation layer 300, and an optical functional layer may be disposed on the touch sensor layer. The touch sensor layer may obtain coordinate information according to an external input, for example, a touch event. The optical functional layer may reduce reflectivity of light (external light) incident on the display apparatus 1 from the outside, and/or may improve the color purity of light emitted from the display apparatus 1. In an embodiment, the optical functional layer may include a retarder and/or a polarizer. The retarder may be of a film type or a liquid crystal coating type, and may include a λ/2 retarder and/or a 80 /4 retarder. The polarizer may also be of a film type or a liquid crystal coating type. The film type may include a stretchable synthetic resin film, and the liquid crystal coating type may include liquid crystals arranged in a certain array. The retarder and the polarizer may further include a protective film.

An adhesive member may be arranged between the touch sensor layer and the optical functional layer. The adhesive member may be any general member that is well-known in the field of technology without limitation. The adhesive member may be a pressure sensitive adhesive (PSA).

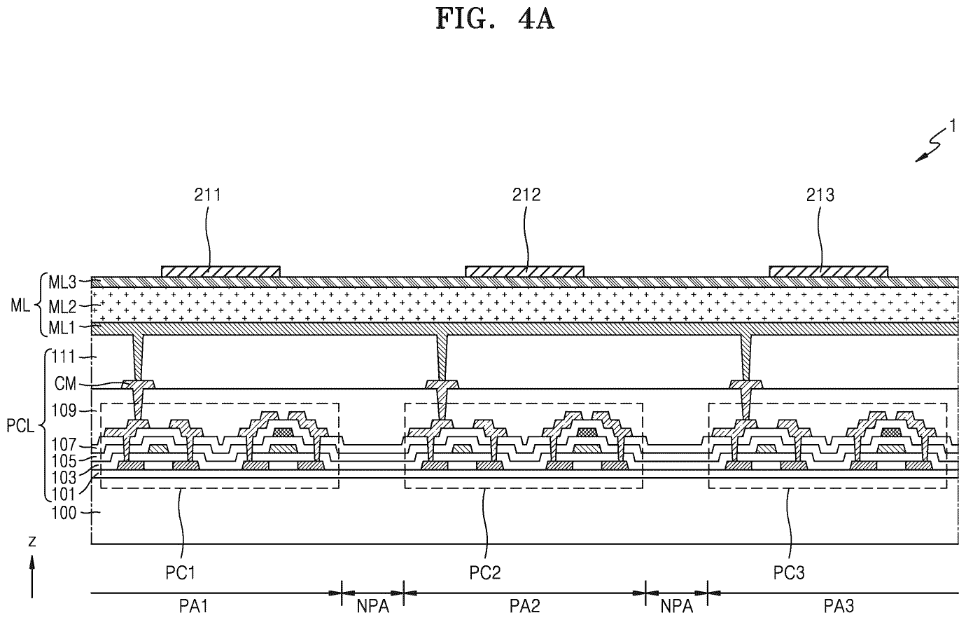

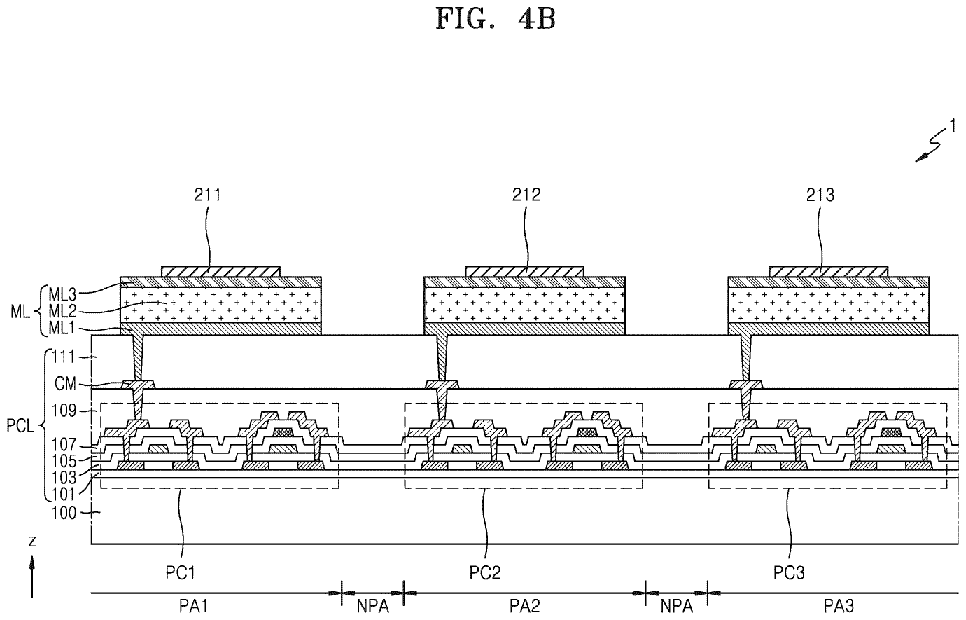

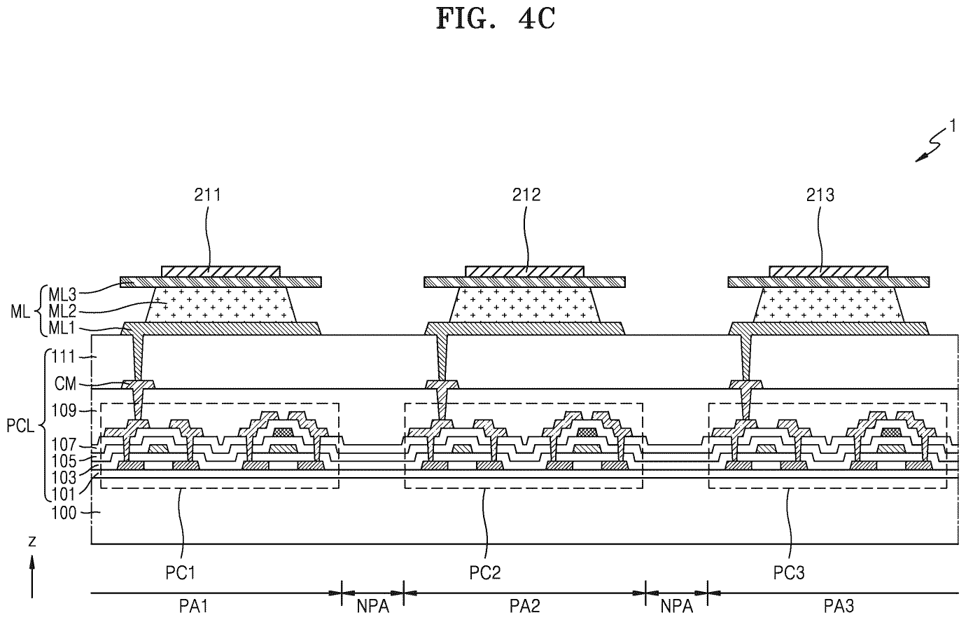

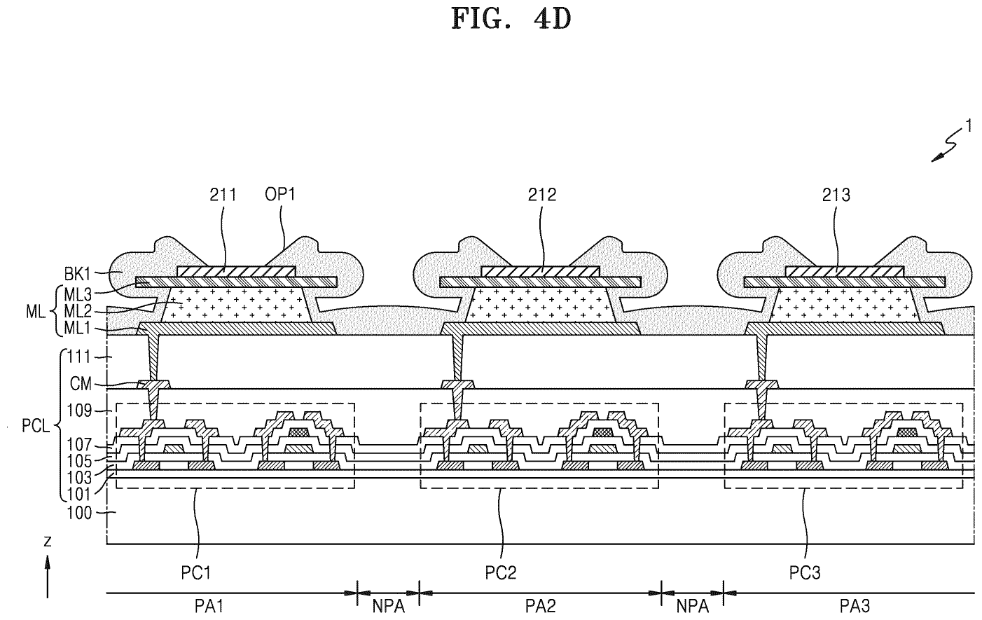

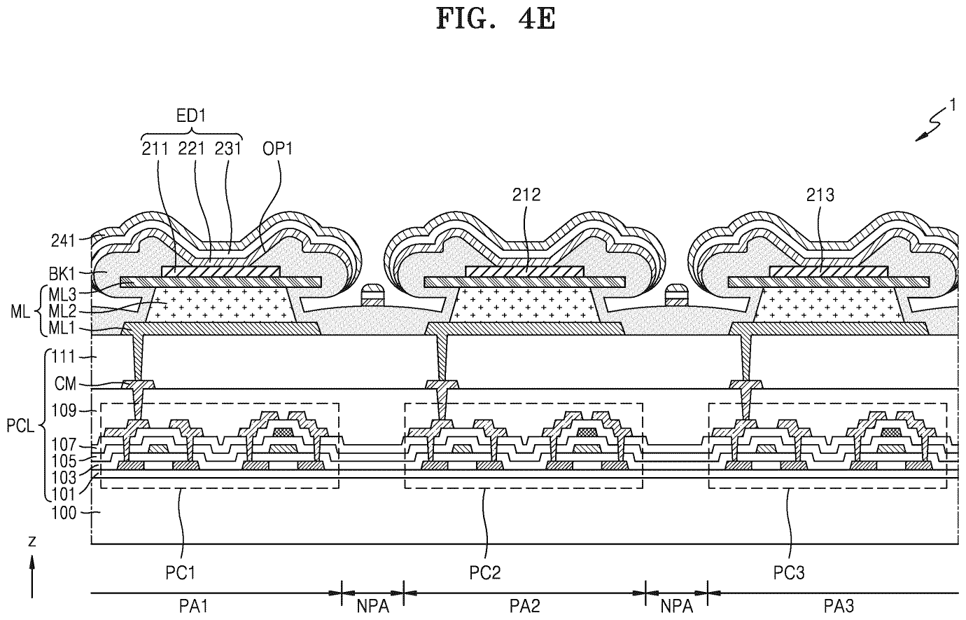

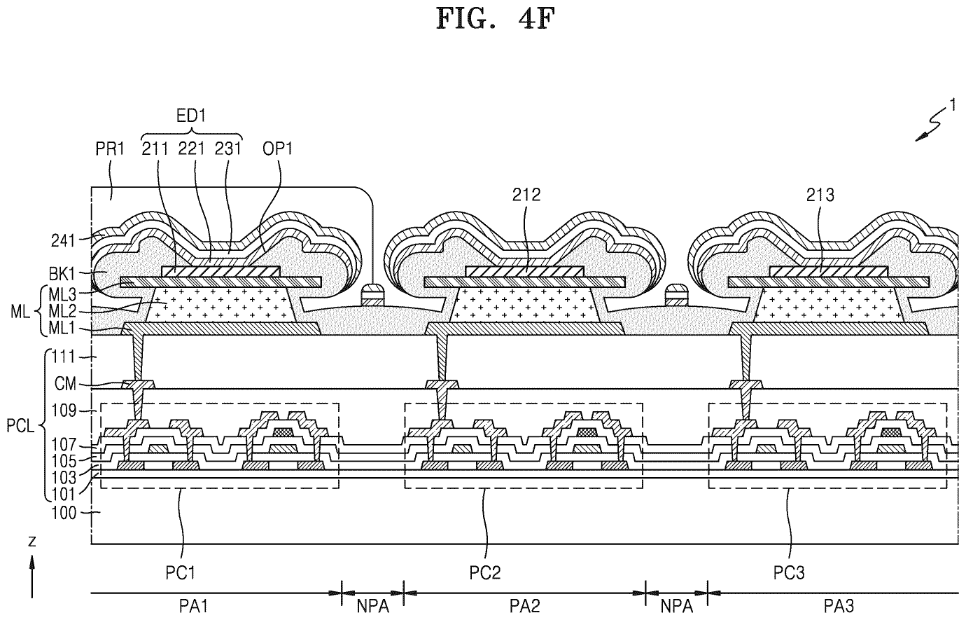

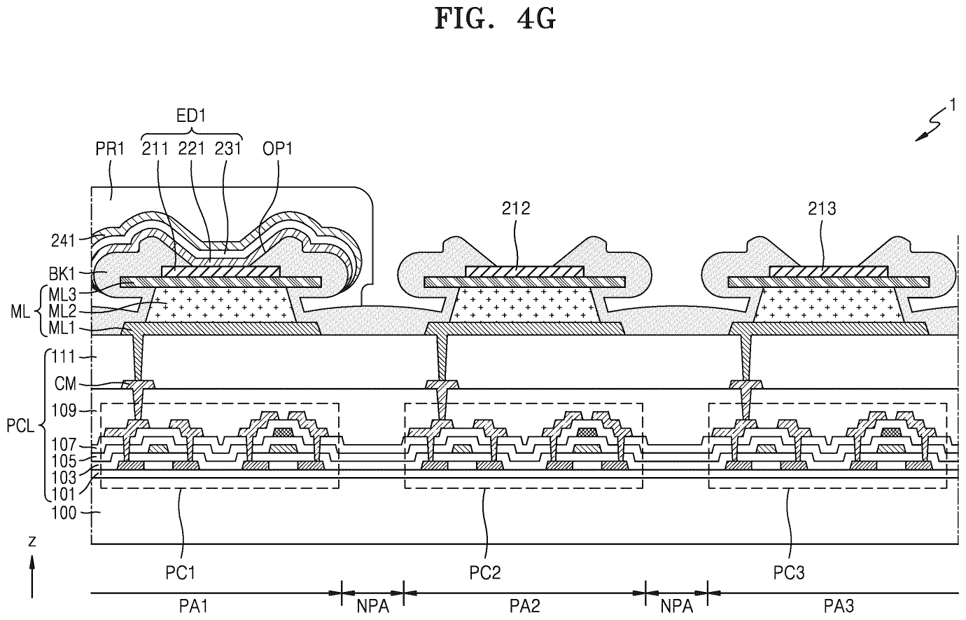

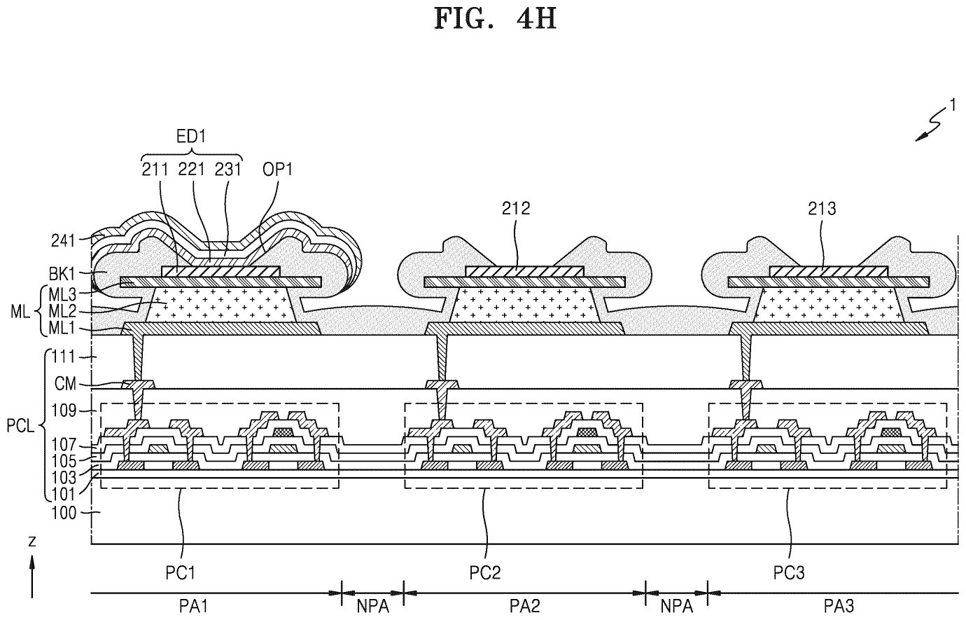

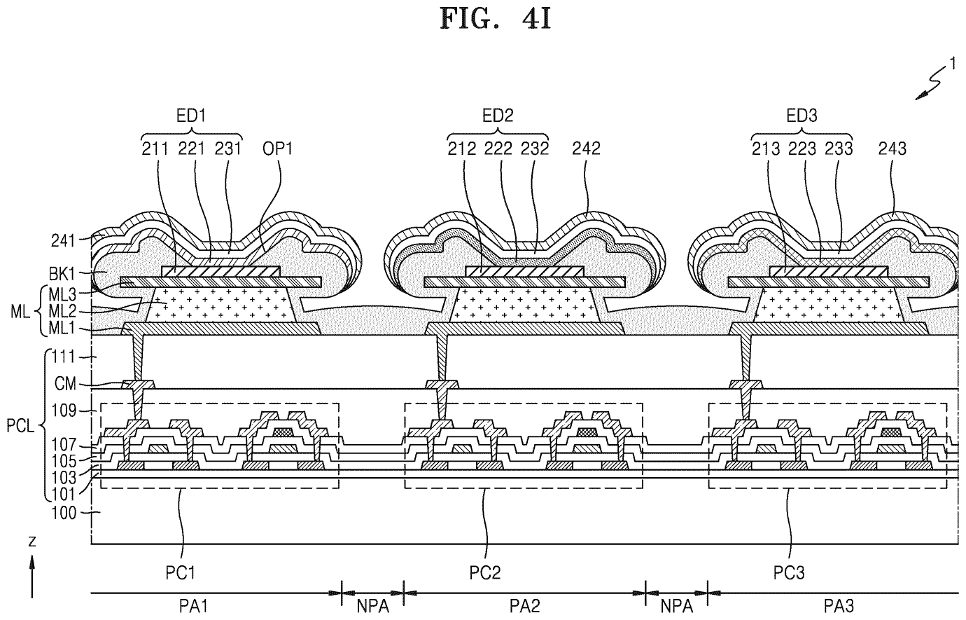

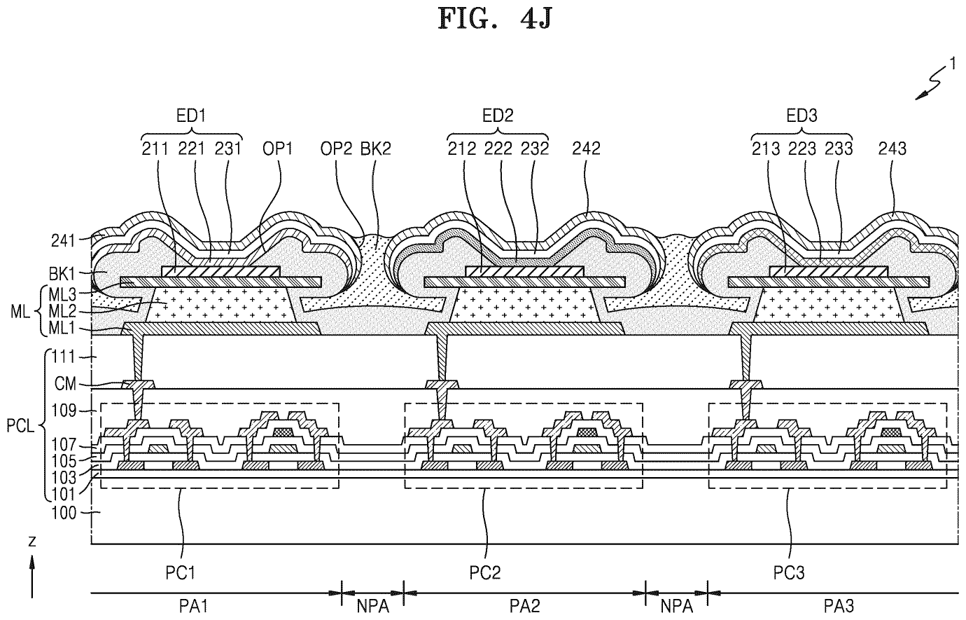

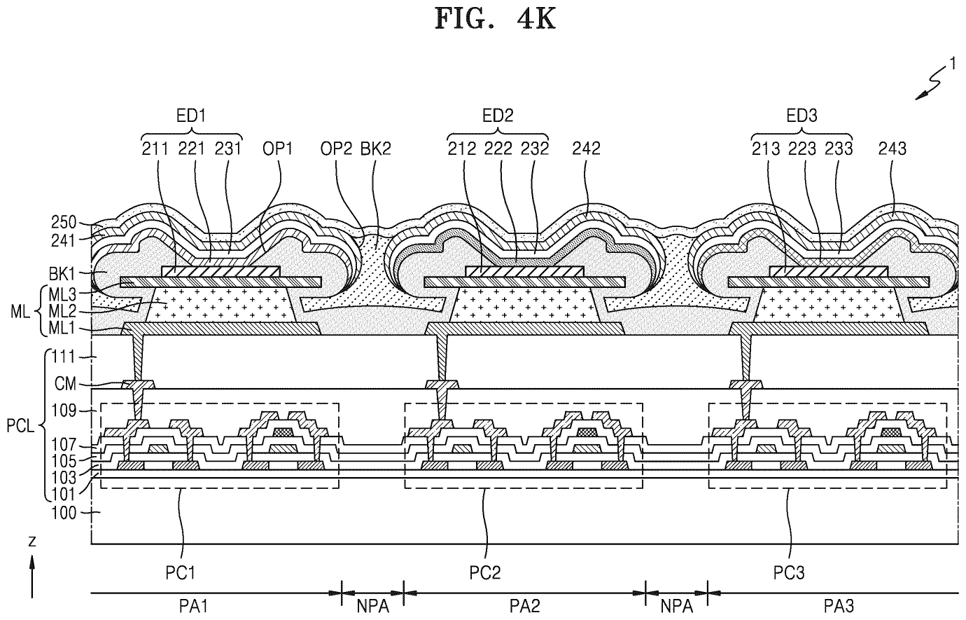

FIGS. 4A to 4K are schematic cross-sectional views of the display apparatus 1 according to an embodiment.

It is possible to understand a method of manufacturing the display apparatus 1 by referring to FIGS. 4A to 4K.

In FIGS. 4A to 4K, reference numerals that are the same as those in FIG. 3A refer to the same components, and redundant explanations thereof are omitted.

Referring to FIG. 4A, a method of manufacturing the display apparatus 1 may include arranging the pixel circuit layer PCL on the substrate 100, arranging the metal layer ML on the pixel circuit layer PCL, and arranging first to third pixel electrodes 211, 212, and 213 on the metal layer ML.

The pixel circuit layer PCL may include a first pixel circuit PC1, a second pixel circuit PC2, and a third pixel circuit PC3. The metal layer ML includes the first metal layer ML1, the second metal layer ML2, and the third metal layer ML3, and may be arranged throughout the first pixel region PA1, the second pixel region PA2, the third pixel region PA3, and the non-pixel region NPA. The first pixel electrode 211 may be arranged in the first pixel region PA1, the second pixel electrode 212 may be arranged in the second pixel region PA2, and the third pixel electrode 213 may be arranged in the third pixel region PA3. The first pixel electrode 211, the second pixel electrode 212, and the third pixel electrode 213 may be arranged apart from each other.

The first pixel circuit PC1, the second pixel circuit PC2, and the third pixel circuit PC3 may correspond to the pixel circuit PC described with reference to FIG. 3A. The first pixel electrode 211, the second pixel electrode 212, and the third pixel electrode 213 may correspond to the pixel electrode 210 described with reference to FIG. 3A.

Referring to FIG. 4B, the method of manufacturing the display apparatus 1 may include etching the metal layer ML.

The metal layer ML may be etched by using a photolithography process. First, a photoresist pattern may be formed on the metal layer ML and the first to third pixel electrodes 211, 212, and 213. Next, the metal layer ML may be etched by using a dry etching process employing an etching gas. Accordingly, the metal layer ML may be separated into a plurality of metal layers ML. The plurality of metal layers ML may be arranged at positions corresponding to the first pixel region PA1, the second pixel region PA2, and the third pixel region PA3. Next, the photoresist pattern may be removed. Known methods may be used for this photolithography process.

The first pixel electrode 211 may be electrically connected to the first pixel circuit PC1 via the metal layer ML, the second pixel electrode 212 may be electrically connected to the second pixel circuit PC2 via the metal layer ML, and the third pixel electrode 213 may be electrically connected to the third pixel circuit PC3 via the metal layer ML.

Referring to FIG. 4C, the method of manufacturing the display apparatus 1 may include etching the second metal layer ML2.

The second metal layer ML2 may include Al. The second metal layer ML2 may be etched by using a wet etching process employing an etchant. In this process, the first metal layer ML1 and the third metal layer ML3 may include a tip portion protruding from the second metal layer ML2 in one direction. In other words, the first metal layer ML1 may be divided into the first-1 metal layer portion ML1-1 (see FIG. 3B) and the first-2 metal layer portion ML1-2 (see FIG. 3B), and the third metal layer ML3 may be divided into the third-1 metal layer portion ML3-1 (see FIG. 3B) and the third-2 metal layer portion ML3-2 (see FIG. 3B).

Referring to FIG. 4D, the method of manufacturing the display apparatus 1 may include arranging the first bank layer BK1 on the first to third pixel electrodes 211, 212, and 213, and forming the first opening OP1 in the first bank layer BK1.

The first bank layer BK1 may cover the pixel circuit layer PCL, the metal layer ML, and the first to third pixel electrodes 211, 212, and 213. The first bank layer BK1 may include a shape that is convex along the third-2 metal layer portion ML3-2 (see FIG. 3B) of the third metal layer ML3.

The first bank layer BK1 may be etched by using a photolithography process. First, a photoresist pattern may be formed on the first bank layer BK1. Next, the first bank layer BK1 may be etched by using a dry etching process employing an etching gas. Accordingly, the first opening OP1 may be formed in the first bank layer BK1. The first opening OP1 may be provided as a plurality of first openings OP1 according to the number of pixels P. For example, the plurality of first openings OP1 may be arranged at positions corresponding to the first pixel region PA1, the second pixel region PA2, and the third pixel region PA3. Next, the photoresist pattern may be removed. Known methods may be used for this photolithography process.

Referring to FIG. 4E, the method of manufacturing the display apparatus 1 may include arranging a first intermediate layer 221 on the first bank layer BK1, arranging a first opposite electrode 231 on the first intermediate layer 221, and arranging a first-1 connection electrode 241 on the first opposite electrode 231.

The first intermediate layer 221, the first opposite electrode 231, and the first-1 connection electrode 241 may be at least partially accommodated in the first opening OP1. At this time, the first pixel electrode 211, the first intermediate layer 221, and the first opposite electrode 231 may form a first light-emitting element ED1.

The first intermediate layer 221 may be arranged in each of the first pixel region PA1, the second pixel region PA2, the third pixel region PA3, and the non-pixel region NPA. However, due to the tip structure of the second metal layer ML2, the first intermediate layers 221 arranged in the first pixel region PA1, the second pixel region PA2, the third pixel region PA3, and the non-pixel region NPA may be spaced apart from each other.

The first opposite electrode 231 may be arranged in each of the first pixel region PA1, the second pixel region PA2, the third pixel region PA3, and the non-pixel region NPA. However, due to the tip structure of the second metal layer ML2, the first opposite electrodes 231 arranged in the first pixel region PA1, the second pixel region PA2, the third pixel region PA3, and the non-pixel region NPA may be spaced apart from each other.

The first-1 connection electrode 241 may be arranged in each of the first pixel region PA1, the second pixel region PA2, the third pixel region PA3, and the non-pixel region NPA. However, due to the tip structure of the second metal layer ML2, the first-1 connection electrodes 241 arranged in the first pixel region PA1, the second pixel region PA2, the third pixel region PA3, and the non-pixel region NPA may be spaced apart from each other.

Referring to FIG. 4F, the method of manufacturing the display apparatus 1 may include arranging a first photoresist layer PR1 in the first pixel region PA1.

The first photoresist layer PR1 may cover the first bank layer BK1, the first intermediate layer 221, the first opposite electrode 231, and the first-1 connection electrode 241, which are arranged in the first pixel region PA1. Accordingly, the first bank layer BK1, the first intermediate layer 221, the first opposite electrode 231, and the first-1 connection electrode 241, which are arranged in the first pixel region PA1, may be sealed from the outside by the first photoresist layer PR1. Accordingly, a phenomenon in which the first intermediate layer 221, the first opposite electrode 231, and the first-1 connection electrode 241, which are arranged in the first pixel region PA1, are damaged in subsequent processes may be reduced.

Referring to FIG. 4G, the method of manufacturing the display apparatus 1 may include removing the first-1 connection electrode 241, removing the first opposite electrode 231, and removing the first intermediate layer 221.

The first-1 connection electrode 241 and the first opposite electrode 231 may be removed by dry etching employing an etching gas. At this time, the first-1 connection electrode 241 and the first opposite electrode 231, which are arranged in the first pixel region PA1, are protected by the first photoresist layer PR1 and thus may not be removed.

In other words, the first intermediate layer 221 may be removed via an ashing process. At this time, the first intermediate layer 221 arranged in the first pixel region PA1 is protected by the first photoresist layer PR1 and thus may not be removed.

Referring to FIGS. 4G and 4H, the method of manufacturing the display apparatus 1 may include removing the first photoresist layer PR1.

Referring to FIG. 4I, the method of manufacturing the display apparatus 1 may include arranging a second intermediate layer 222 on the first bank layer BK1, arranging a second opposite electrode 232 on the second intermediate layer 222, and arranging a first-2 connection electrode 242 on the second opposite electrode 232. The second pixel electrode 212, the second intermediate layer 222, and the second opposite electrode 232 may form a second light-emitting element ED2.

In addition, the method of manufacturing the display apparatus 1 may include arranging a third intermediate layer 223 on the first bank layer BK1, arranging a third opposite electrode 233 on the third intermediate layer 223, and arranging a first-3 connection electrode 243 on the third opposite electrode 233. The third pixel electrode 213, the third intermediate layer 223, and the third opposite electrode 233 may form a third light-emitting element ED3.

These processes are substantially the same as the processes described with reference to FIGS. 4E to 4H, and thus detailed descriptions are omitted.

The first intermediate layer 221, the second intermediate layer 222, and the third intermediate layer 223 may correspond to the intermediate layer 220 described with reference to FIG. 3A. The first opposite electrode 231, the second opposite electrode 232, and the third opposite electrode 233 may correspond to the opposite electrode 230 described with reference to FIG. 3A. The first-1 connection electrode 241, the first-2 connection electrode 242, and the first-3 connection electrode 243 may correspond to the first connection electrode 240 described with reference to FIG. 3A. The first light-emitting element ED1, the second light-emitting element ED2, and the third light-emitting element ED3 may correspond to the light-emitting element ED described with reference to FIG. 3A.

The first intermediate layer 221 of the first light-emitting element ED1, the second intermediate layer 222 of the second light-emitting element ED2, and the third intermediate layer 223 of the third light-emitting element ED3 may emit light of different colors. For example, the first intermediate layer 221 of the first light-emitting element ED1 may emit red light, the second intermediate layer 222 of the second light-emitting element ED2 may emit green light, and the third intermediate layer 223 of the third light-emitting element ED3 may emit blue light.

Referring to FIG. 4J, the method of manufacturing the display apparatus 1 may include arranging the second bank layer BK2 on the first bank layer BK1.

The second bank layer BK2 may cover, at least partially, the first-1 connection electrode 241, the first-2 connection electrode 242, and the first-3 connection electrode 243. In other words, the second opening OP2 in the second bank layer BK2 may accommodate, at least partially, the first intermediate layer 221, the first opposite electrode 231, and the first-1 connection electrode 241. In addition, the second opening OP2 in the second bank layer BK2 may accommodate, at least partially, the second intermediate layer 222, the second opposite electrode 232, and the first-2 connection electrode 242. In addition, the second opening OP2 in the second bank layer BK2 may accommodate, at least partially, the third intermediate layer 223, the third opposite electrode 233, and the first-3 connection electrode 243.

Referring to FIG. 4K, the method of manufacturing the display apparatus 1 may include arranging the second connection electrode 250 on the second bank layer BK2. The second connection electrode 250 may be in contact with each of the first-1 connection electrode 241, the first-2 connection electrode 242, and the first-3 connection electrode 243.

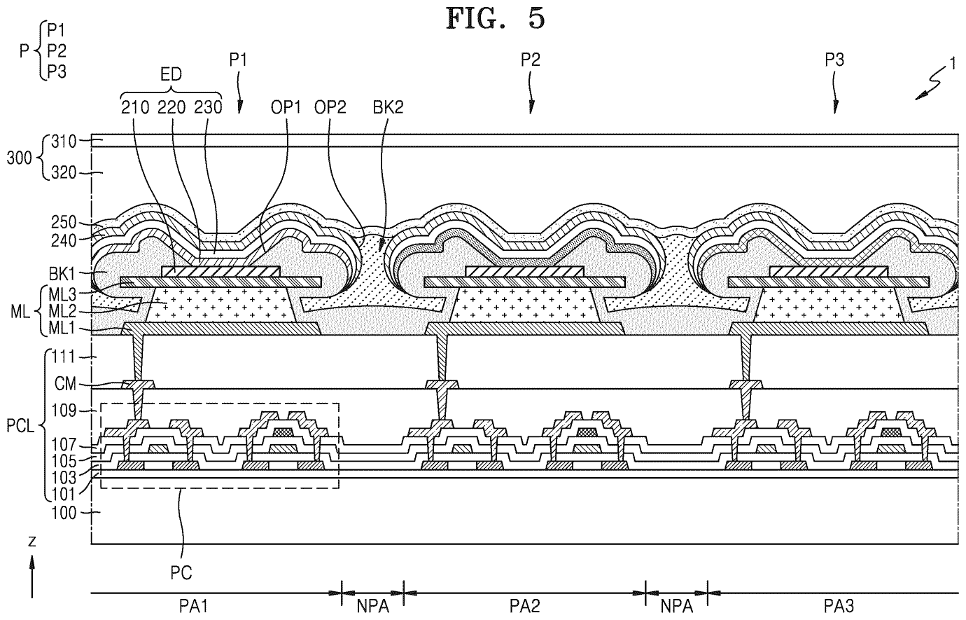

FIG. 5 is a schematic cross-sectional view of the display apparatus 1 according to an embodiment.

In FIG. 5, reference numerals that are the same as those in FIGS. 3A and 3B refer to the same components, and redundant explanations thereof are omitted.

Referring to FIG. 5, the display apparatus 1 may include the substrate 100, the pixel circuit layer PCL, the metal layer ML, the light-emitting element ED, the first bank layer BK1, the second bank layer BK2, the first connection electrode 240, the second connection electrode 250, and the encapsulation layer 300.

The pixel P shown in FIG. 5 may include the first pixel P1, the second pixel P2, and the third pixel P3. At this time, in the display apparatus 1, a region in which the first pixel P1 is arranged is referred to as the first pixel region PA1, a region in which the second pixel P2 is arranged is referred to as the second pixel region PA2, and a region in which the third pixel P3 is arranged is referred to as the third pixel region PA3. The display apparatus 1 may include the first to third pixel regions PA1, PA2, and PA3 and the non-pixel region NPA between neighboring pixel regions.

The substrate 100 may include glass material or polymer resin. The substrate 100 may include a structure in which a base layer including polymer resin and an inorganic barrier layer are stacked.

The pixel circuit layer PCL may be disposed on the substrate 100. The pixel circuit layer PCL may include the buffer layer 101, the first gate insulating layer 103, the first interlayer insulating layer 105, the second interlayer insulating layer 107, the first organic insulating layer 109, the second organic insulating layer 111, and the pixel circuit PC. The metal layer ML may be disposed on the pixel circuit layer PCL. The metal layer ML may include the first metal layer ML1, the second metal layer ML2, and the third metal layer ML3. The pixel circuit PC and the metal layer ML may be electrically connected to each other via the connection metal CM.

The light-emitting element ED may be disposed on the third metal layer ML3 of the metal layer ML. The light-emitting element ED may include the pixel electrode 210, the intermediate layer 220, and the opposite electrode 230. The pixel electrode 210, the intermediate layer 220, and the opposite electrode 230 may be sequentially arranged in a stacked structure.

The first bank layer BK1 may be disposed on the pixel electrode 210 to cover the pixel circuit layer PCL and the metal layer ML. The intermediate layer 220 may be disposed on the pixel electrode 210 and the first bank layer BK1. The opposite electrode 230 may be disposed on the intermediate layer 220. The first connection electrode 240 may be disposed on the opposite electrode 230. The second bank layer BK2 may be disposed on the first bank layer BK1 to cover at least a portion of the first bank layer BK1. The second connection electrode 250 may cover the first connection electrode 240 and the second bank layer BK2.

The encapsulation layer 300 may be disposed on the second connection electrode 250. The encapsulation layer 300 may include one inorganic encapsulation layer and one organic encapsulation layer 320.

As shown in FIG. 5, the encapsulation layer 300 may include the organic encapsulation layer 320 and the first inorganic encapsulation layer 310, which are sequentially stacked.

The organic encapsulation layer 320 may be disposed on the second connection electrode 250 to be in contact with the second connection electrode 250, and the first inorganic encapsulation layer 310 may be disposed on the organic encapsulation layer 320.

In this structure, the second connection electrode 250 functions as an inorganic encapsulation layer, and thus, a separate inorganic encapsulation layer arranged between the second connection electrode 250 and the organic encapsulation layer 320 may be omitted.

According to the display apparatus 1 described with reference to FIGS. 3A to 5, due to the tip structure of the third metal layer ML3, the intermediate layers 220 arranged in the first pixel region PA1, the second pixel region PA2, and the third pixel region PA3 may be spaced apart from each other. In other words, a phenomenon in which the first intermediate layer 221, the second intermediate layer 222, and the third intermediate layer 223 are in contact with each other may be reduced. Accordingly, a lateral leakage phenomenon of the intermediate layer 220 may be reduced.

In addition, the width of the pixel electrode 210 is smaller than the width of the third metal layer ML3, and thus, an external light reflection phenomenon that occurs in the pixel electrode 210 may be reduced. In addition, the second bank layer BK2 includes a black organic material and/or a black inorganic material, and thus, an external light reflection phenomenon that occurs in a side surface of the metal layer ML may be reduced.

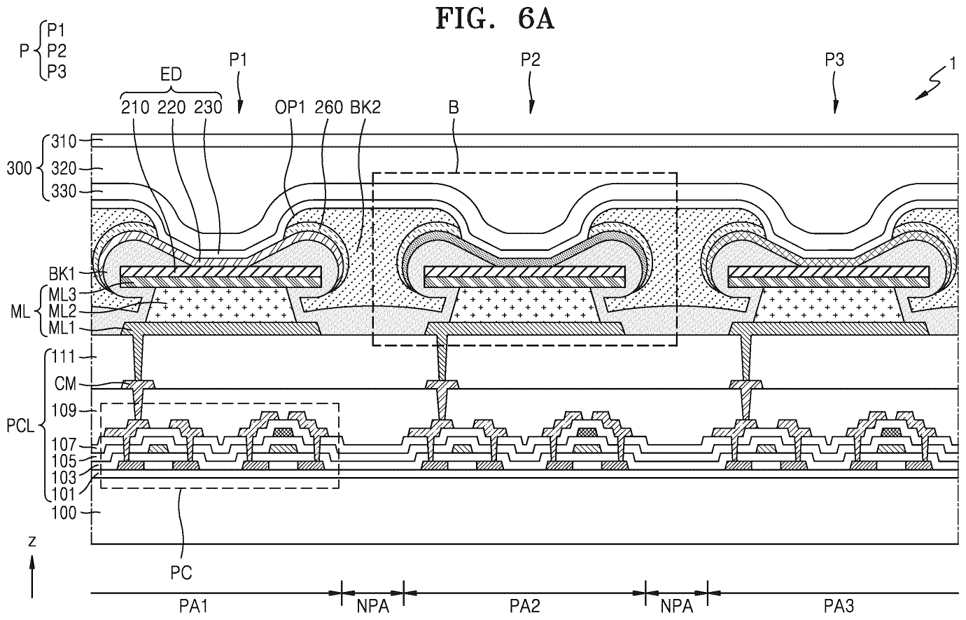

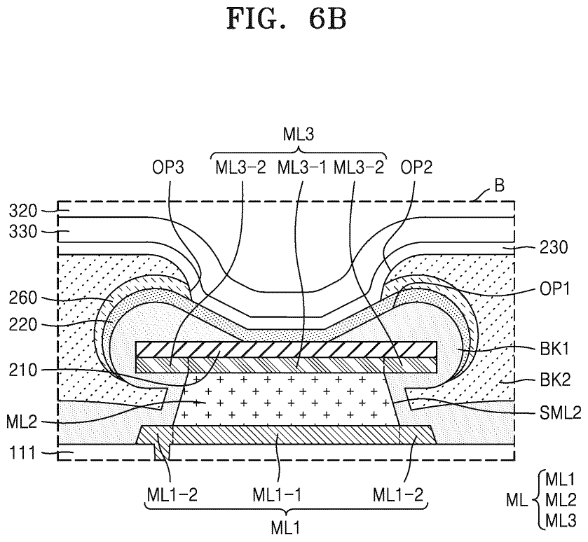

FIGS. 6A and 6B are schematic cross-sectional views of the display apparatus 1 according to an embodiment.

In detail, FIG. 6B is an enlarged view of a region B of FIG. 6A.

In FIGS. 6A and 6B, reference numerals that are the same as those in FIGS. 3A and 3B refer to the same components, and redundant explanations thereof are omitted.

Referring to FIGS. 6A and 6B, the display apparatus 1 may include the substrate 100, the pixel circuit layer PCL, the metal layer ML, the light-emitting element ED, the first bank layer BK1, the second bank layer BK2, a reflective layer 260, and the encapsulation layer 300.

The pixel P shown in FIGS. 6A and 6B may include the first pixel P1, the second pixel P2, and the third pixel P3. At this time, in the display apparatus 1, a region in which the first pixel P1 is arranged is referred to as the first pixel region PA1, a region in which the second pixel P2 is arranged is referred to as the second pixel region PA2, and a region in which the third pixel P3 is arranged is referred to as the third pixel region PA3. The display apparatus 1 may include the first to third pixel regions PA1, PA2, and PA3 and the non-pixel region NPA between neighboring pixel regions.

At this time, the light-emitting element ED may be provided as a plurality of light-emitting elements ED to correspond to a plurality of pixel regions. For example, as shown in FIG. 6A, three light-emitting elements ED may be provided to correspond to the first to third pixel regions PA1, PA2, and PA3.

The substrate 100 may include glass material or polymer resin. The substrate 100 may include a structure in which a base layer including polymer resin and an inorganic barrier layer are stacked.

The pixel circuit layer PCL may be disposed on the substrate 100. The pixel circuit layer PCL may include the buffer layer 101, the first gate insulating layer 103, the first interlayer insulating layer 105, the second interlayer insulating layer 107, the first organic insulating layer 109, the second organic insulating layer 111, and the pixel circuit PC. The buffer layer 101 may be disposed on an upper surface of the substrate 100. The buffer layer 101 may prevent penetration of impurities into a semiconductor layer of a transistor.

The first gate insulating layer 103 may be disposed on the buffer layer 101. The first interlayer insulating layer 105 may be disposed on the first gate insulating layer 103. The first organic insulating layer 109 may be disposed on the pixel circuit PC. The connection metal CM may be disposed on the first organic insulating layer 109. The second organic insulating layer 111 may be arranged between the connection metal CM and the metal layer ML. The pixel circuit PC may be disposed on the buffer layer 101. The pixel circuit PC may be arranged between the substrate 100 and the light-emitting element ED.

The metal layer ML may be disposed on the pixel circuit layer PCL. The metal layer ML may include the first metal layer ML1, the second metal layer ML2, and the third metal layer ML3.

The first metal layer ML1 may be disposed on the pixel circuit layer PCL and electrically connected to the pixel circuit PC. For example, the first metal layer ML1 may contact the connection metal CM through the second organic insulating layer 111. The second metal layer ML2 may be disposed on the first metal layer ML1, and the third metal layer ML3 may be disposed on the second metal layer ML2.

The first metal layer ML1 and the third metal layer ML3 may include a same material. For example, the first metal layer ML1 and the third metal layer ML3 may each include Ti. The second metal layer ML2 may include a different material from each of the first metal layer ML1 and the third metal layer ML3. For example, the second metal layer ML2 may include Al, Ag, Mg, Pt, Pd, Au, Ni, Nd, Ir, or Cr, or a compound thereof. However, the materials constituting the first metal layer ML1, the second metal layer ML2, and the third metal layer ML3 are only examples and are not limited to the above-described examples.

The second metal layer ML2 may have a smaller width than the first metal layer ML1. The third metal layer ML3 may have a larger width than the second metal layer ML2. The first metal layer ML1 and the third metal layer ML3 may have a same width.

The first metal layer ML1 may include the first-1 metal layer portion ML1-1 overlapping the second metal layer ML2, and the first-2 metal layer portion ML1-2 extending from the first-1 metal layer portion ML1-1. The first-2 metal layer portion ML1-2 may be arranged outside the first-1 metal layer portion ML1-1.

In addition, the third metal layer ML3 may include the third-1 metal layer portion ML3-1 overlapping the second metal layer ML2, and the third-2 metal layer portion ML3-2 extending from the third-1 metal layer portion ML3-1. The third-2 metal layer portion ML3-2 may be arranged outside the third-1 metal layer portion ML3-1.

The first-1 metal layer portion ML1-1 and the third-1 metal layer portion ML3-1 may overlap each other. In addition, the first-2 metal layer portion ML1-2 and the third-2 metal layer portion ML3-2 may overlap each other.

In this structure, the first metal layer ML1 and the third metal layer ML3 may include a tip structure protruding from the second metal layer ML2 in one direction. For example, the first-2 metal layer portion ML1-2 and the third-2 metal layer portion ML3-2 may have a tip structure protruding from the second metal layer ML2 in one direction.

The light-emitting element ED may be disposed on the third metal layer ML3 of the metal layer ML. The light-emitting element ED may include the pixel electrode 210, the intermediate layer 220, and the opposite electrode 230. The pixel electrode 210, the intermediate layer 220, and the opposite electrode 230 may be sequentially arranged in a stacked structure.

The pixel electrode 210 may be disposed on the third metal layer ML3 of the metal layer ML. The pixel electrode 210 may be electrically connected to the pixel circuit PC via the metal layer ML. The width of the pixel electrode 210 may be the same as the width of the third metal layer ML3. The pixel electrode 210 may include metal and/or conductive oxide. The pixel electrode 210 may include ITO, IZO, ZnO, or In₂O₃, or a compound thereof.

The first bank layer BK1 may be disposed on the pixel electrode 210 to cover the pixel circuit layer PCL and the metal layer ML. The first bank layer BK1 may be in contact with the side surface SML2 of the second metal layer ML2. The first bank layer BK1 may include a shape that is convex along the third-2 metal layer portion ML3-2 and the pixel electrode 210. The first bank layer BK1 may include the first opening OP1 extending to and exposing at least a portion of the pixel electrode 210. The first bank layer BK1 may include an organic insulating material and/or an inorganic insulating material. The first opening OP1 may define an emission region of light emitted from the light-emitting element ED. For example, the size/width of the first opening OP1 may correspond to the size/width of the emission region. Accordingly, the size and/or width of the pixel P may depend on the size and/or width of the first opening OP1 in the first bank layer BK1.

The intermediate layer 220 may be disposed on the pixel electrode 210 and the first bank layer BK1. The intermediate layer 220 may include a polymer or low-molecular weight organic material that emits light of a certain color. In an embodiment, the intermediate layer 220 may include an inorganic light-emitting material or a quantum dot.

At least a portion of the intermediate layer 220 may be accommodated in the first opening OP1 and be in contact with the pixel electrode 210. The inner portion of the intermediate layer 220 may overlap and be in contact with the pixel electrode 210, and the outer portion may extend onto the first bank layer BK1 and overlap and be in contact with the first bank layer BK1. In this regard, the expression “the other portion of A” indicates “a portion of A including the edge of A,” and the expression “the inner portion of A” indicates another portion of A surrounded by the outer portion.

The reflective layer 260 may be disposed on the intermediate layer 220. The reflective layer 260 may cover at least a portion of the intermediate layer 220. The reflective layer 260 may include a third opening OP3 above and overlapping the first opening OP1. The third opening OP3 may overlap the pixel electrode 210 and the intermediate layer 220. At least a portion of the intermediate layer 220 may be exposed from the reflective layer 260 via the third opening OP3. For example, the reflective layer 260 may include Al, Ag, Mg, Pt, Pd, Au, Ni, Nd, Ir, or Cr, or a compound thereof.

The intermediate layer 220 and the reflective layer 260 may be provided in the form of an isolated island. The intermediate layer 220 arranged in the first pixel region PA1, the intermediate layer 220 arranged in the second pixel region PA2, and the intermediate layer 220 arranged in the third pixel region PA3 may not be in contact with each other. The reflective layer 260 arranged in the first pixel region PA1, the reflective layer 260 arranged in the second pixel region PA2, and the reflective layer 260 arranged in the third pixel region PA3 may not be in contact with each other.

The second bank layer BK2 may be disposed on the first bank layer BK1 to cover at least a portion of the reflective layer 260. The second bank layer BK2 may be arranged in the non-pixel region NPA. For example, the second bank layer BK2 is arranged between the first bank layer BK1 arranged in the first pixel region PA1, the first bank layer BK1 arranged in the second pixel region PA2, and the first bank layer BK1 arranged in the third pixel region PA3, and thus may serve as a planarization layer.

The second bank layer BK2 may include the second opening OP2 above and overlapping the first opening OP1 and the third opening OP3. The intermediate layer 220 and the reflective layer 260 may be accommodated in the second opening OP2. The second bank layer BK2 may include an organic insulating material and/or an inorganic insulating material. The second bank layer BK2 may include a black organic material and/or a black inorganic material.

The opposite electrode 230 may cover the second bank layer BK2. The opposite electrode 230 may be in contact with the intermediate layer 220 via the first opening OP1, the second opening OP2, and the third opening OP3. At least a portion of the opposite electrode 230 may be accommodated in the first opening OP1, the second opening OP2, and the third opening OP3. The opposite electrode 230 may include a conductive material having a low work function. For example, the opposite electrode 230 may include a (semi) transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof. In an embodiment, the opposite electrode 230 may further include a layer including ITO, IZO, ZnO, or In₂O₃ on the (semi) transparent layer including the above-described material. The opposite electrode 230 may be a common layer that is arranged throughout the first pixel region PA1, the second pixel region PA2, the third pixel region PA3, and the non-pixel region NPA.

The encapsulation layer 300 may be disposed on the opposite electrode 230. The encapsulation layer 300 includes at least one inorganic encapsulation layer and at least one organic encapsulation layer 320, and in an embodiment, FIG. 6A shows that the encapsulation layer 300 includes the second inorganic encapsulation layer 330, the organic encapsulation layer 320, and the first inorganic encapsulation layer 310, which are sequentially stacked. The second inorganic encapsulation layer 330 may be disposed on the opposite electrode 230 to be in contact with the opposite electrode 230, the organic encapsulation layer 320 may be disposed on the second inorganic encapsulation layer 330, and the first inorganic encapsulation layer 310 may be disposed on the organic encapsulation layer 320.

The first inorganic encapsulation layer 310 and the second inorganic encapsulation layer 330 may include at least one organic material among aluminum oxide, titanium oxide, tantalum oxide, hafnium oxide, zinc oxide, silicon oxide, silicon nitride, and silicon oxynitride. The organic encapsulation layer 320 may include a polymer-based material. The polymer-based material may include acrylic resin, epoxy-based resin, PI, and polyethylene. In an embodiment, the organic encapsulation layer 320 may include acrylate. The organic encapsulation layer 320 may be formed by curing a monomer or applying a polymer. The organic encapsulation layer 320 may have transparency.

Although not shown, a touch sensor layer may be disposed on the encapsulation layer 300, and an optical functional layer may be disposed on the touch sensor layer. The touch sensor layer may obtain coordinate information according to an external input, for example, a touch event. The optical functional layer may reduce reflectivity of light (external light) incident on the display apparatus 1 from the outside, and/or may improve the color purity of light emitted from the display apparatus 1. In an embodiment, the optical functional layer may include a retarder and/or a polarizer. The retarder may be of a film type or a liquid crystal coating type, and may include λ/2 retarder and/or a λ/4 retarder. The polarizer may also be of a film type or a liquid crystal coating type. The film type may include a stretchable synthetic resin film, and the liquid crystal coating type may include liquid crystals arranged in a certain array. The retarder and the polarizer may further include a protective film.

An adhesive member may be arranged between the touch sensor layer and the optical functional layer. The adhesive member may be any general member that is well-known in the field of technology without limitation. The adhesive member may be a pressure sensitive adhesive (PSA).

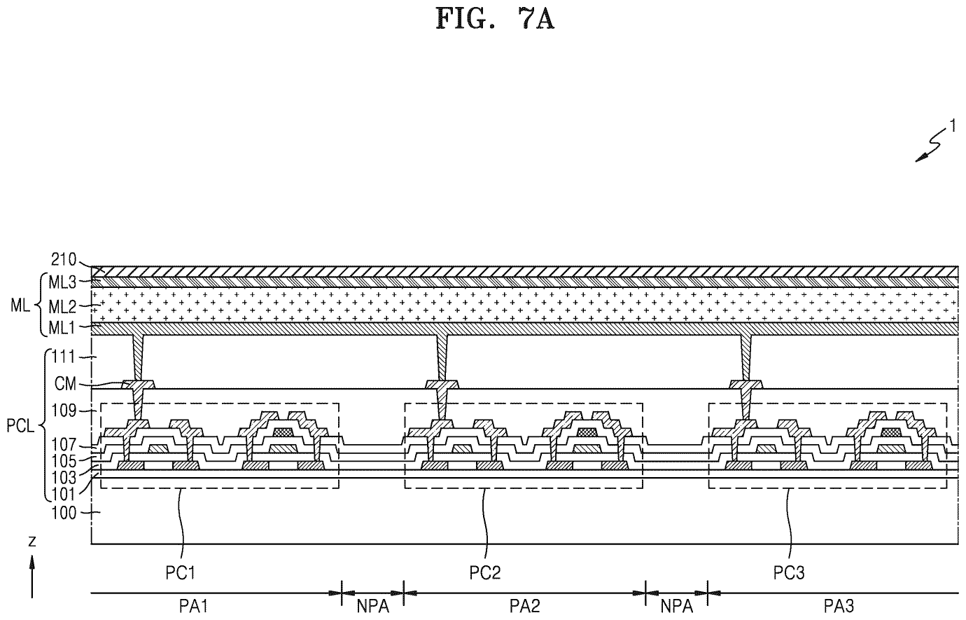

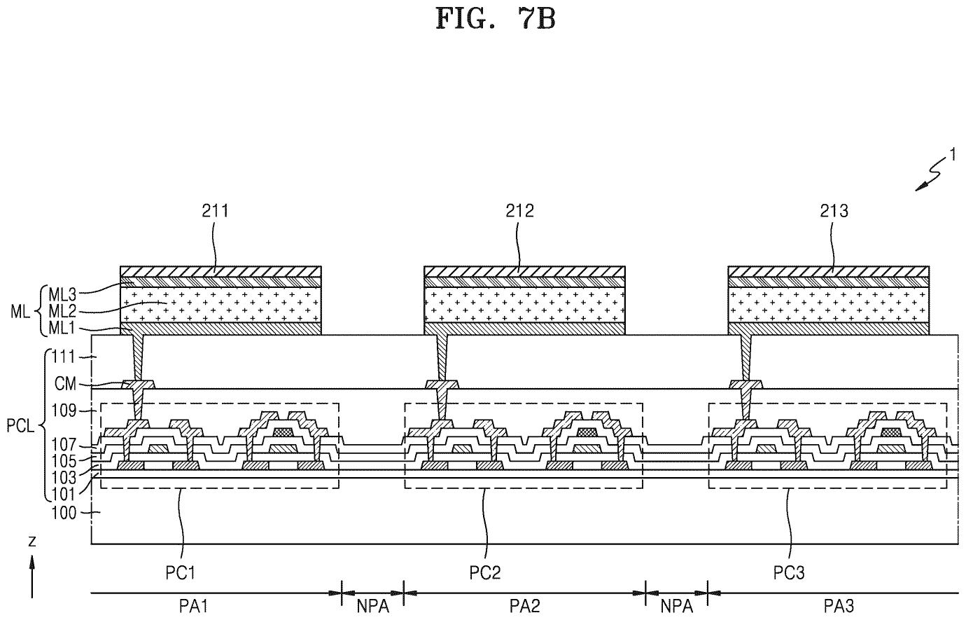

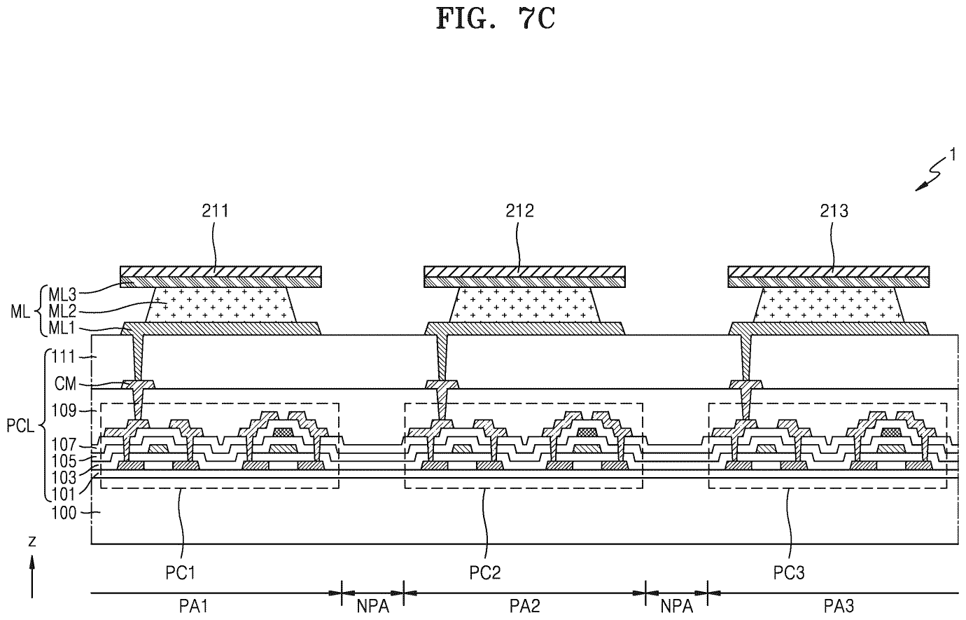

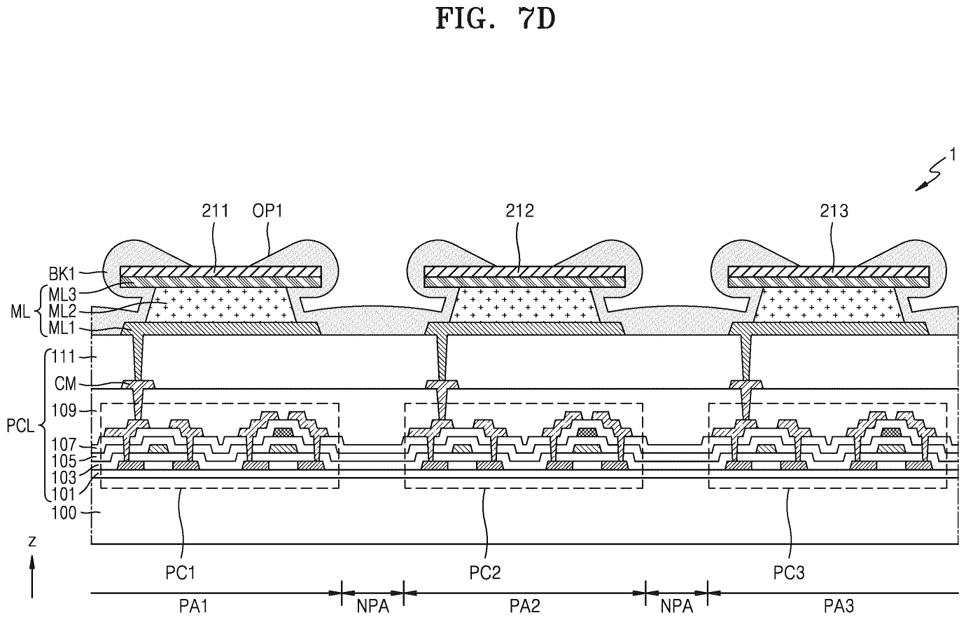

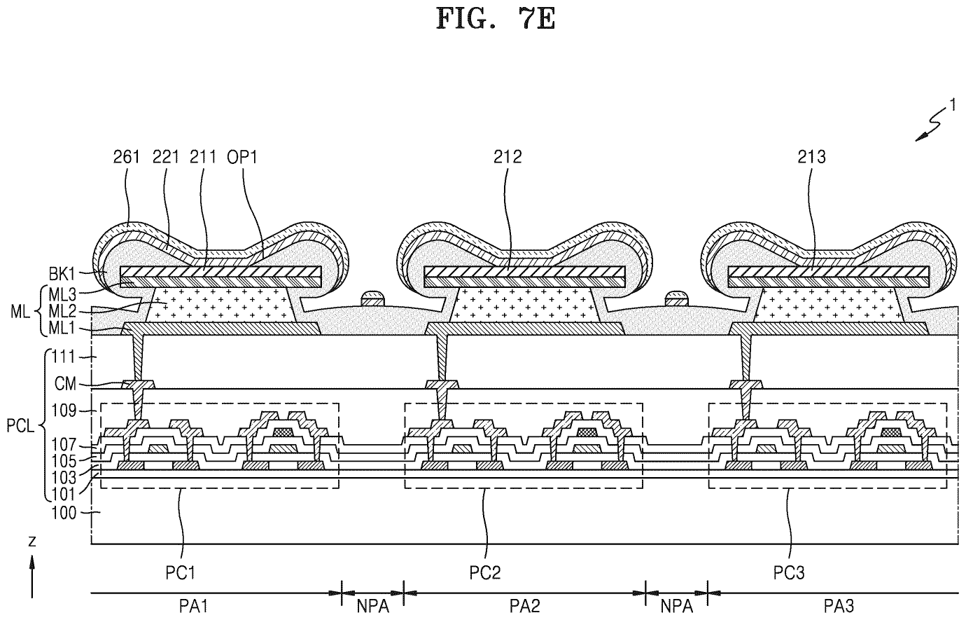

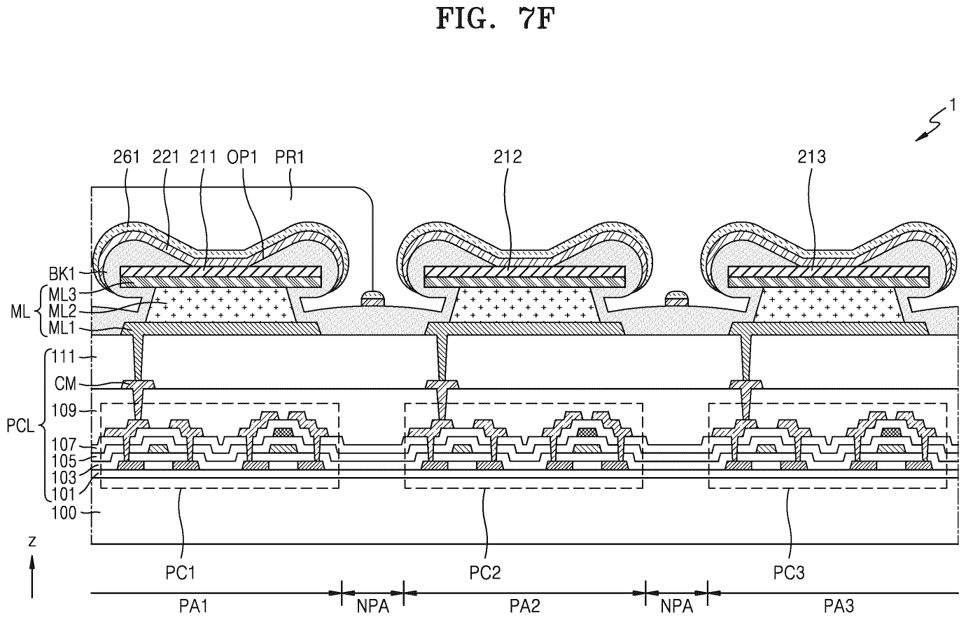

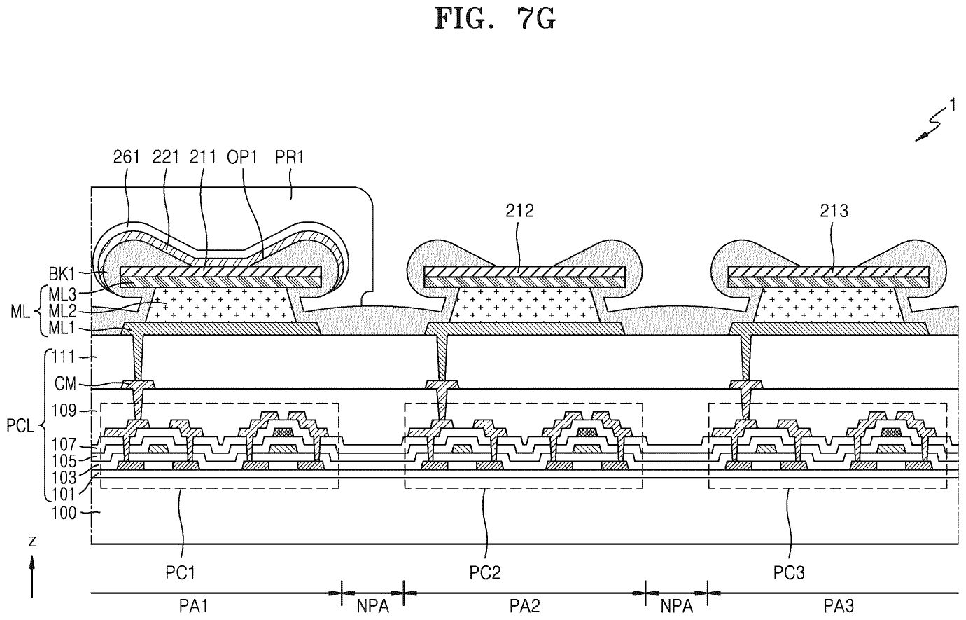

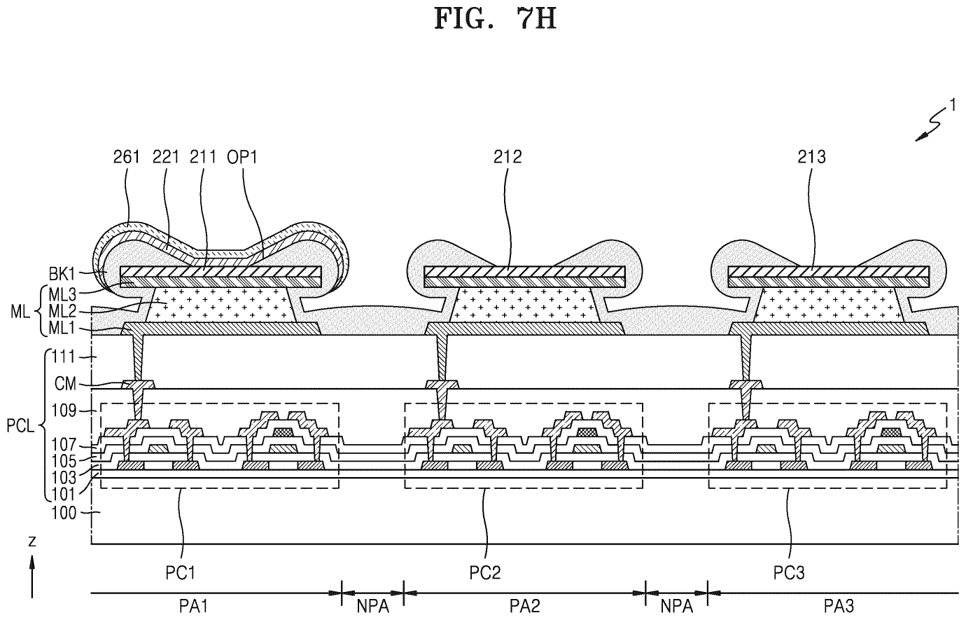

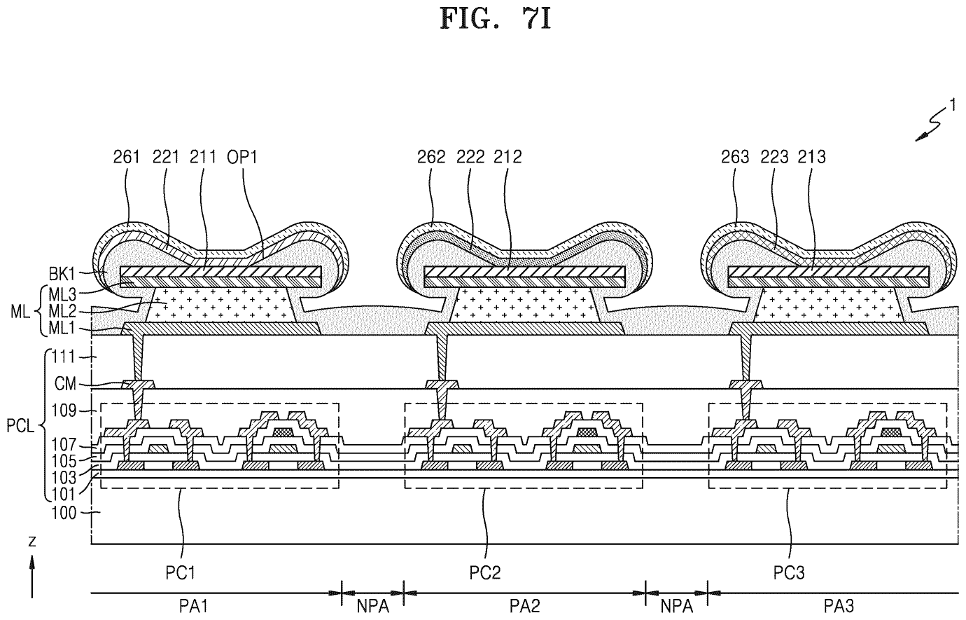

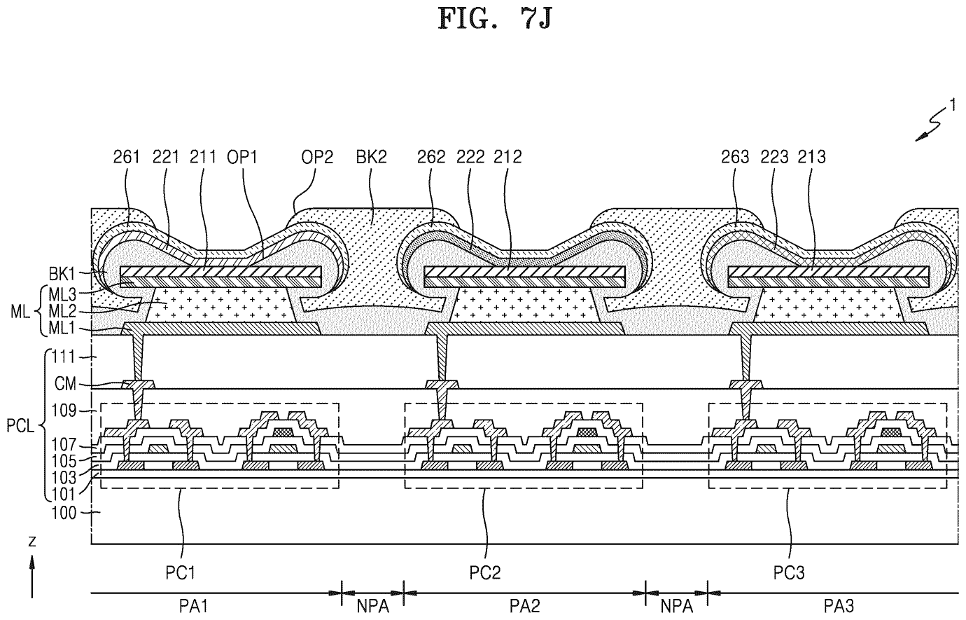

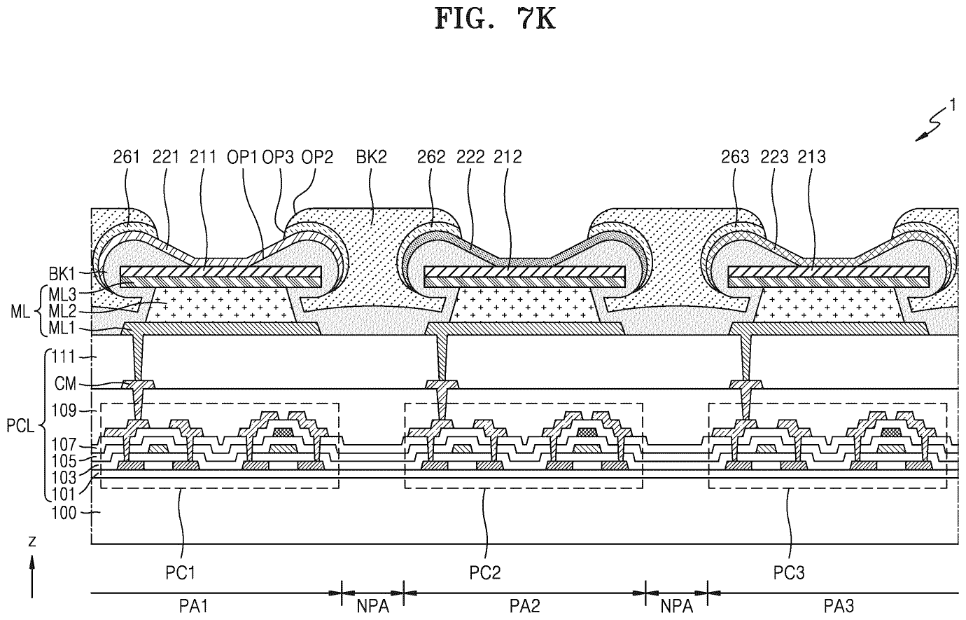

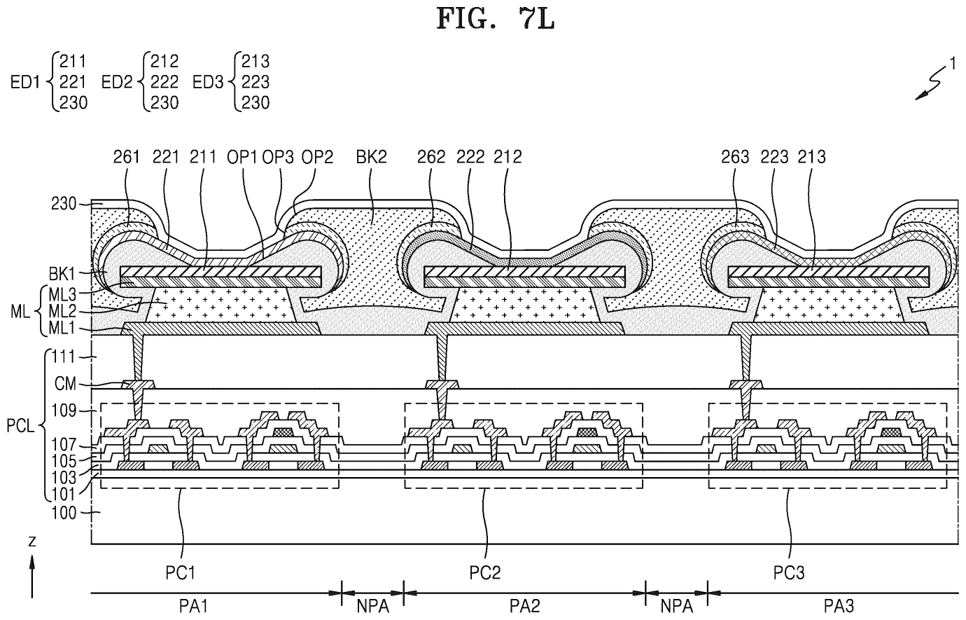

FIGS. 7A to 7L are schematic cross-sectional views of the display apparatus 1 according to an embodiment.

It is possible to understand a method of manufacturing the display apparatus 1 by referring to FIGS. 7A to 7L.

In FIGS. 7A to 7L, reference numerals that are the same as those in FIG. 6A refer to the same components, and redundant explanations thereof are omitted.

Referring to FIG. 7A, a method of manufacturing the display apparatus 1 may include arranging the pixel circuit layer PCL on the substrate 100, arranging the metal layer ML on the pixel circuit layer PCL, and arranging the pixel electrode 210 on the metal layer ML.

The pixel circuit layer PCL may include the first pixel circuit PC1, the second pixel circuit PC2, and the third pixel circuit PC3. The first pixel circuit PC1, the second pixel circuit PC2, and the third pixel circuit PC3 may correspond to the pixel circuit PC described with reference to FIG. 6A.

The metal layer ML may include the first metal layer ML1, the second metal layer ML2, and the third metal layer ML3. The metal layer ML and the pixel electrode 210 may be arranged throughout the first pixel region PA1, the second pixel region PA2, the third pixel region PA3, and the non-pixel region NPA.

Referring to FIGS. 7A and 7B, the method of manufacturing the display apparatus 1 may include etching the pixel electrode 210 and the metal layer ML.

The pixel electrode 210 and the metal layer ML may be etched by using a photolithography process. First, a photoresist pattern may be formed on the pixel electrode 210. Next, the pixel electrode 210 and the metal layer ML may be etched by using a dry etching process employing an etching gas. Accordingly, the pixel electrode 210 and the metal layer ML may be respectively separated into a plurality of pixel electrodes 210 and a plurality of metal layers ML. The plurality of pixel electrodes 210 and the plurality of metal layers ML may be arranged at positions corresponding to the first pixel region PA1, the second pixel region PA2, and the third pixel region PA3. Next, the photoresist pattern may be removed. Known methods may be used for this photolithography process.

The pixel electrode 210 may be separated into a plurality of pixel electrodes 210 and thus divided into the first pixel electrode 211, the second pixel electrode 212, and the third pixel electrode 213. The first pixel electrode 211 may be electrically connected to the first pixel circuit PC1 via the metal layer ML, the second pixel electrode 212 may be electrically connected to the second pixel circuit PC2 via the metal layer ML, and the third pixel electrode 213 may be electrically connected to the third pixel circuit PC3 via the metal layer ML. The first pixel electrode 211, the second pixel electrode 212, the third pixel electrode 213, and the plurality of metal layers ML may have a same width.

Referring to FIG. 7C, the method of manufacturing the display apparatus 1 may include etching the second metal layer ML2.

The second metal layer ML2 may include Al. The second metal layer ML2 may be etched by using a wet etching process employing an etchant. In this process, the first metal layer ML1 and the third metal layer ML3 may include a tip portion protruding from the second metal layer ML2 in one direction. In other words, the first metal layer ML1 may be divided into the first-1 metal layer portion ML1-1 (see FIG. 6B) and the first-2 metal layer portion ML1-2 (see FIG. 6B), and the third metal layer ML3 may be divided into the third-1 metal layer portion ML3-1 (see FIG. 6B) and the third-2 metal layer portion ML3-2 (see FIG. 6B).

Referring to FIG. 7D, the method of manufacturing the display apparatus 1 may include arranging the first bank layer BK1 on the first to third pixel electrodes 211, 212, and 213, and forming the first opening OP1 in the first bank layer BK1. The first bank layer BK1 may cover the pixel circuit layer PCL, the metal layer ML, and the first to third pixel electrodes 211, 212, and 213. The first bank layer BK1 may include a shape that is convex along the third-2 metal layer portion ML3-2 (see FIG. 6B) of the third metal layer ML3.

The first bank layer BK1 may be etched by using a photolithography process. First, a photoresist pattern may be formed on the first bank layer BK1. Next, the first bank layer BK1 may be etched by using a dry etching process employing an etching gas. Accordingly, the first opening OP1 may be formed in the first bank layer BK1. The first opening OP1 may be provided as a plurality of first openings OP1 according to the number of pixels P. For example, the plurality of first openings OP1 may be arranged at positions corresponding to the first pixel region PA1, the second pixel region PA2, and the third pixel region PA3. Next, the photoresist pattern may be removed. Known methods may be used for this photolithography process.

Referring to FIG. 7E, the method of manufacturing the display apparatus 1 may include arranging the first intermediate layer 221 on the first bank layer BK1 and arranging a first reflective layer 261 on the first intermediate layer 221.

The first intermediate layer 221 and the first reflective layer 261 may be at least partially accommodated in the first opening OP1.

The first intermediate layer 221 may be arranged in each of the first pixel region PA1, the second pixel region PA2, the third pixel region PA3, and the non-pixel region NPA. However, due to the tip structure of the second metal layer ML2, the first intermediate layers 221 arranged in the first pixel region PA1, the second pixel region PA2, the third pixel region PA3, and the non-pixel region NPA may be spaced apart from each other.

The first reflective layer 261 may be arranged in each of the first pixel region PA1, the second pixel region PA2, the third pixel region PA3, and the non-pixel region NPA. However, due to the tip structure of the second metal layer ML2, the first reflective layers 261 arranged in the first pixel region PA1, the second pixel region PA2, the third pixel region PA3, and the non-pixel region NPA may be spaced apart from each other.

The first reflective layer 261 may cover the first intermediate layer 221. The first intermediate layer 221 may be sealed by the first reflective layer 261. The first intermediate layer 221 is protected by the first reflective layer 261, and thus, a phenomenon in which the first intermediate layer 221 and the first reflective layer 261, which are arranged in the first pixel region PA1, are damaged in subsequent processes may be reduced.

Referring to FIG. 7F, the method of manufacturing the display apparatus 1 may include arranging the first photoresist layer PR1 in the first pixel region PA1.

The first photoresist layer PR1 may cover the first bank layer BK1, the first intermediate layer 221, and the first reflective layer 261, which are arranged in the first pixel region PA1. Accordingly, the first bank layer BK1, the first intermediate layer 221, and the first reflective layer 261, which are arranged in the first pixel region PA1, may be sealed from the outside by the first photoresist layer PR1.

Referring to FIG. 7G, the method of manufacturing the display apparatus 1 may include removing the first reflective layer 261 and removing the first intermediate layer 221.

The first reflective layer 261 may be removed by dry etching employing an etching gas. At this time, the first reflective layer 261 arranged in the first pixel region PA1 is protected by the first photoresist layer PR1 and thus may not be removed.

The first intermediate layer 221 may be removed via an ashing process. At this time, the first intermediate layer 221 arranged in the first pixel region PA1 is protected by the first photoresist layer PR1 and thus may not be removed.

Referring to FIGS. 7G and 7H, the method of manufacturing the display apparatus 1 may include removing the first photoresist layer PR1.

Referring to FIG. 7I, the method of manufacturing the display apparatus 1 may include arranging the second intermediate layer 222 on the first bank layer BK1 and arranging a second reflective layer 262 on the second intermediate layer 222.

In addition, the method of manufacturing the display apparatus 1 may include arranging the third intermediate layer 223 on the first bank layer BK1 and arranging a third reflective layer 263 on the third intermediate layer 223.

These processes are substantially the same as the processes described with reference to FIGS. 7E to 7H, and thus detailed descriptions are omitted.

Referring to FIG. 7J, the method of manufacturing the display apparatus 1 may include arranging the second bank layer BK2 on the first bank layer BK1.

The second bank layer BK2 may cover, at least partially, the first reflective layer 261, the second reflective layer 262, and the third reflective layer 263. In other words, the second opening OP2 in the second bank layer BK2 may accommodate, at least partially, the first intermediate layer 221 and the first reflective layer 261. In addition, the second

opening OP2 in the second bank layer BK2 may accommodate, at least partially, the second intermediate layer 222 and the second reflective layer 262. In addition, the second opening OP2 in the second bank layer BK2 may accommodate, at least partially, the third intermediate layer 223 and the third reflective layer 263.

Referring to FIG. 7K, the method of manufacturing the display apparatus 1 may include etching the first to third reflective layers 261, 262, and 263.

The first to third reflective layers 261, 262, and 263 may include Al. The first to third reflective layers 261, 262, and 263 may be etched by using a wet etching process employing an etchant. Portions of the first to third reflective layers 261, 262, and 263, which overlap the second opening OP2, may be exposed to an etchant and thus etched. Accordingly, the third opening OP3 overlapping the second opening OP2 may be formed in the first to third reflective layers 261, 262, and 263. Portions of the first to third reflective layers 261, 262, and 263, which do not overlap the second opening OP2, are protected by the second bank layer BK2 and thus may not be etched. The first to third reflective layers 261, 262, and 263 may serve as sacrificial layers.

Referring to FIG. 7L, the method of manufacturing the display apparatus 1 may include arranging the opposite electrode 230 on the second bank layer BK2. The opposite electrode 230 may be in contact with each of the first intermediate layer 221, the second intermediate layer 222, and the third intermediate layer 223.

The first pixel electrode 211, the first intermediate layer 221, and the opposite electrode 230 may form the first light-emitting element ED1. The second pixel electrode 212, the second intermediate layer 222, and the opposite electrode 230 may form the second light-emitting element ED2. The third pixel electrode 213, the third intermediate layer 223, and the opposite electrode 230 may form the third light-emitting element ED3.

The first intermediate layer 221, the second intermediate layer 222, and the third intermediate layer 223 may correspond to the intermediate layer 220 described with reference to FIG. 6A. The first reflective layer 261, the second reflective layer 262, and the third reflective layer 263 may correspond to the reflective layer 260 described with reference to FIG. 6A. The first light-emitting element ED1, the second light-emitting element ED2, and the third light-emitting element ED3 may correspond to the light-emitting element ED described with reference to FIG. 6A.

The first intermediate layer 221 of the first light-emitting element ED1, the second intermediate layer 222 of the second light-emitting element ED2, and the third intermediate layer 223 of the third light-emitting element ED3 may emit light of different colors. For example, the first intermediate layer 221 of the first light-emitting element ED1 may emit red light, the second intermediate layer 222 of the second light-emitting element ED2 may emit green light, and the third intermediate layer 223 of the third light-emitting element ED3 may emit blue light.

Referring to FIGS. 7K and 7L, the first intermediate layer 221 may be exposed to the outside from the second bank layer BK2 immediately before the opposite electrode 230 is deposited. In addition, the second intermediate layer 222 may be exposed to the outside from the second bank layer BK2 immediately before the opposite electrode 230 is deposited. In addition, the third intermediate layer 223 may be exposed to the outside from the second bank layer BK2 immediately before the opposite electrode 230 is deposited. Accordingly, the time during which the first intermediate layer 221, the second intermediate layer 222, and the third intermediate layer 223 are exposed to the atmosphere may be reduced.

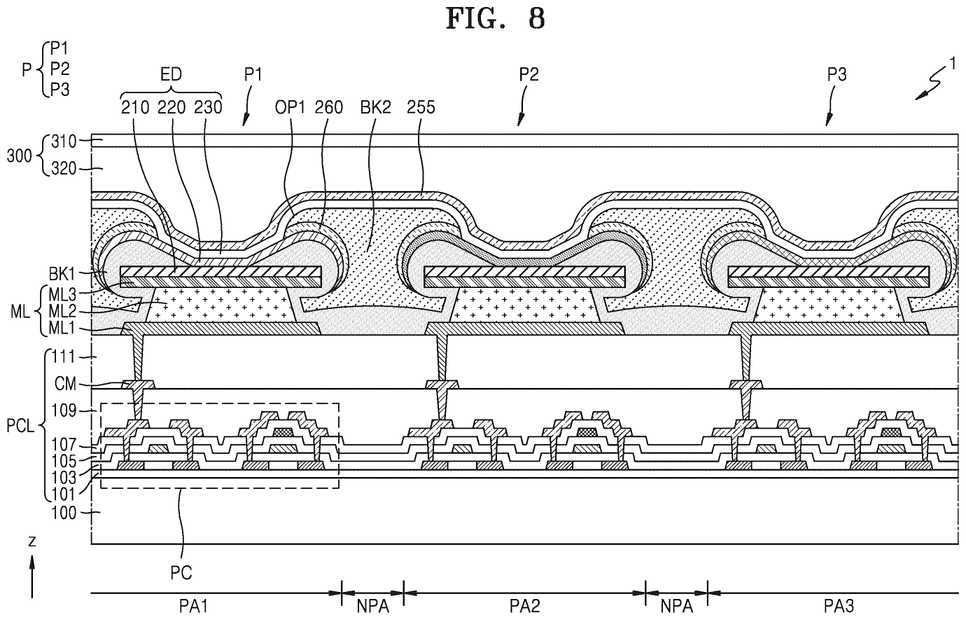

FIG. 8 is a schematic cross-sectional view of the display apparatus 1 according to an embodiment.

In FIG. 8, reference numerals that are the same as those in FIGS. 6A and 6B refer to the same components, and redundant explanations thereof are omitted.

Referring to FIG. 5, the display apparatus 1 may include the substrate 100, the pixel circuit layer PCL, the metal layer ML, the light-emitting element ED, the first bank layer BK1, the second bank layer BK2, the reflective layer 260, and the encapsulation layer 300.

The pixel P shown in FIG. 8 may include the first pixel P1, the second pixel P2, and the third pixel P3. At this time, in the display apparatus 1, a region in which the first pixel P1 is arranged is referred to as the first pixel region PA1, a region in which the second pixel P2 is arranged is referred to as the second pixel region PA2, and a region in which the third pixel P3 is arranged is referred to as the third pixel region PA3. The display apparatus 1 may include the first to third pixel regions PA1, PA2, and PA3 and the non-pixel region NPA between neighboring pixel regions.

The substrate 100 may include glass material or polymer resin. The substrate 100 may include a structure in which a base layer including polymer resin and an inorganic barrier layer are stacked.

The pixel circuit layer PCL may be disposed on the substrate 100. The pixel circuit layer PCL may include the buffer layer 101, the first gate insulating layer 103, the first interlayer insulating layer 105, the second interlayer insulating layer 107, the first organic insulating layer 109, the second organic insulating layer 111, and the pixel circuit PC.

The metal layer ML may be disposed on the pixel circuit layer PCL. The metal layer ML may include the first metal layer ML1, the second metal layer ML2, and the third metal layer ML3. The pixel circuit PC and the metal layer ML may be electrically connected to each other via the connection metal CM.

The light-emitting element ED may be disposed on the third metal layer ML3 of the metal layer ML. The light-emitting element ED may include the pixel electrode 210, the intermediate layer 220, and the opposite electrode 230. The pixel electrode 210, the intermediate layer 220, and the opposite electrode 230 may be sequentially arranged in a stacked structure.

The first bank layer BK1 may be disposed on the pixel electrode 210 to cover the pixel circuit layer PCL and the metal layer ML. The intermediate layer 220 may be disposed on the pixel electrode 210 and the first bank layer BK1. The reflective layer 260 may be disposed on the intermediate layer 220. The second bank layer BK2 may be disposed on the first bank layer BK1 to cover at least a portion of the reflective layer 260. The opposite electrode 230 may cover the second bank layer BK2.

A third connection electrode 255 may be disposed on the opposite electrode 230. The third connection electrode 255 may be in contact with the opposite electrode 230. The third connection electrode 255 may be a common layer that is arranged throughout the first pixel region PA1, the second pixel region PA2, the third pixel region PA3, and the non-pixel region NPA. The third connection electrode 255 may include a TCO.

The encapsulation layer 300 may be disposed on the third connection electrode 255. The encapsulation layer 300 may include one inorganic encapsulation layer and one organic encapsulation layer 320.

As shown in FIG. 8, the encapsulation layer 300 may include the organic encapsulation layer 320 and the first inorganic encapsulation layer 310, which are sequentially stacked.

The organic encapsulation layer 320 may be disposed on the third connection electrode 255 to be in contact with the third connection electrode 255, and the first inorganic encapsulation layer 310 may be disposed on the organic encapsulation layer 320.

In this structure, the third connection electrode 255 functions as an inorganic encapsulation layer, and thus, a separate inorganic encapsulation layer arranged between the third connection electrode 255 and the organic encapsulation layer 320 may be omitted.

According to the display apparatus 1 described with reference to FIGS. 6A to 8, due to the tip structure of the third metal layer ML3, the intermediate layers 220 arranged in the first pixel region PA1, the second pixel region PA2, and the third pixel region PA3 may be spaced apart from each other. In other words, a phenomenon in which the first intermediate layer 221, the second intermediate layer 222, and the third intermediate layer 223 are in contact with each other may be reduced. Accordingly, a lateral leakage phenomenon of the intermediate layer 220 may be reduced.

In addition, light emitted from the intermediate layer 220 may be sequentially reflected by the reflective layer 260 and the pixel electrode 210 and be emitted to the outside. A phenomenon in which light emitted at a high angle from the intermediate layer 220 is totally reflected by the opposite electrode 230 and thus is not emitted to the outside may be reduced. In other words, the light efficiency of the display apparatus 1 may be improved.

According to the embodiments of the disclosure, durability of a display apparatus may be improved.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
a substrate;
a pixel circuit layer disposed on the substrate and comprising a pixel circuit;
a metal layer disposed on the pixel circuit layer;
a pixel electrode disposed on the metal layer;
a first bank layer disposed on the pixel electrode to cover the metal layer and comprising a first opening extending to at least a portion of the pixel electrode;
an intermediate layer disposed on the pixel electrode and the first bank layer;
an opposite electrode disposed on the intermediate layer;
a first connection electrode disposed on the opposite electrode; and
a second bank layer disposed on the first bank layer to cover at least a portion of the first connection electrode and comprising a second opening overlapping the first opening,
wherein the metal layer comprises:
a first metal layer electrically connected to the pixel circuit;
a second metal layer disposed on the first metal layer and having a width smaller than a width of the first metal layer; and
a third metal layer disposed on the second metal layer and having a width larger than the width of the second metal layer.

2. The display apparatus of claim 1, wherein the second bank layer comprises a black organic material.

3. The display apparatus of claim 1, wherein the first bank layer is in contact with a side surface of the second metal layer.

4. The display apparatus of claim 1, wherein the pixel electrode has a width smaller than the width of the third metal layer.

5. The display apparatus of claim 1, wherein the opposite electrode and the first connection electrode are in a form of an isolated island.

6. The display apparatus of claim 1, wherein the first metal layer and the third metal layer comprise a same material, and
the second metal layer comprises a material different from the material of the first metal layer and the third metal layer.

7. The display apparatus of claim 6, wherein each of the first metal layer and the third metal layer comprises titanium (Ti), and the second metal layer comprises aluminum (Al).

8. The display apparatus of claim 1, further comprising a second connection electrode covering the first connection electrode and the second bank layer.

9. The display apparatus of claim 8, further comprising an encapsulation layer comprising an organic encapsulation layer disposed on the second connection electrode to be in contact with the second connection electrode, and a first inorganic encapsulation layer disposed on the organic encapsulation layer.

10. The display apparatus of claim 8, further comprising an encapsulation layer comprising a second inorganic encapsulation layer disposed on the second connection electrode to be in contact with the second connection electrode, an organic encapsulation layer disposed on the second inorganic encapsulation layer, and a first inorganic encapsulation layer disposed on the organic encapsulation layer.

11. A display apparatus comprising:
a substrate;
a pixel circuit layer disposed on the substrate and comprising a pixel circuit;
a metal layer disposed on the pixel circuit layer;
a pixel electrode disposed on the metal layer;
a first bank layer disposed on the pixel electrode to cover the metal layer and comprising a first opening extending to at least a portion of the pixel electrode;
an intermediate layer disposed on the pixel electrode and the first bank layer;
a reflective layer disposed on the intermediate layer;
a second bank layer disposed on the first bank layer to cover at least a portion of the reflective layer and comprising a second opening overlapping the first opening; and
an opposite electrode covering the second bank layer, wherein the reflective layer comprises a third opening overlapping the first opening, and the opposite electrode is in contact with the intermediate layer via the third opening.

12. The display apparatus of claim 11, wherein the second bank layer comprises a black organic material.

13. The display apparatus of claim 11, wherein the metal layer comprises:
a first metal layer electrically connected to the pixel circuit;
a second metal layer disposed on the first metal layer and having a width smaller than a width of the first metal layer; and
a third metal layer disposed on the second metal layer and having a width larger than the width of the second metal layer.

14. The display apparatus of claim 13, wherein the first bank layer is in contact with a side surface of the second metal layer.

15. The display apparatus of claim 13, wherein the pixel electrode has a width the same as the width of the third metal layer.

16. The display apparatus of claim 13, wherein the first metal layer and the third metal layer comprise a same material, and
the second metal layer comprises a material different from the material of the first metal layer and the third metal layer.

17. The display apparatus of claim 16, wherein each of the first metal layer and the third metal layer comprises titanium (Ti), and
the second metal layer comprises aluminum (Al).

18. The display apparatus of claim 11, wherein the reflective layer is in a form of an isolated island.

19. The display apparatus of claim 11, further comprising:
a third connection electrode disposed on the opposite electrode to be in contact with the opposite electrode; and
an encapsulation layer comprising an organic encapsulation layer disposed on the third connection electrode and a first inorganic encapsulation layer disposed on the organic encapsulation layer.

20. The display apparatus of claim 11, further comprising an encapsulation layer comprising a third inorganic encapsulation layer disposed on the opposite electrode to be in contact with the opposite electrode, an organic encapsulation layer disposed on the third inorganic encapsulation layer, and a first inorganic encapsulation layer disposed on the organic encapsulation layer.
